(19) United States
(12) Patent Application Publication
(10) Pub. No.: US 2026/0089916 A1
(43) Pub. Date: Mar. 26, 2026

(54) SEMICONDUCTOR DEVICE AND SEMICONDUCTOR MEMORY DEVICE

(71) Applicant: Kioxia Corporation, Tokyo (JP)

(72) Inventors: Ha HOANG, Yokkaichi Mie (JP); Kazuhiro MATSUO, Kuwana Mie (JP); Masaya TODA, Yokkaichi Mie (JP); Takuma DOI, Suzuka Mie (JP); Shunichi YONEDA, Yokkaichi Mie (JP); Takumi EDA, Yokkaichi Mie (JP); Yusuke KASAHARA, Yokkaichi Mie (JP); Kazuhiro KATONO, Mie Mie (JP); Takuya KIKUCHI, Yokkaichi Mie (JP); Tadamoto ANZAI, Yokkaichi Mie (JP); Seiichi URAKAWA, Yokkaichi Mie (JP); Yoshinori KITAMURA, Tsu Mie (JP); Momoka OTANI, Yokkaichi Mie (JP)

(73) Assignee: Kioxia Corporation, Tokyo (JP)

(21) Appl. No.: 19/066,433

(22) Filed: Feb. 28, 2025

(30) Foreign Application Priority Data
Sep. 20, 2024 (JP) 2024-164458

(51) Int. Cl. H10B 12/00

(52) U.S. Cl. CPC H10B 12/315; H10B 12/05

(57) ABSTRACT

A semiconductor device of embodiments includes: a first electrode; a second electrode; a first oxide semiconductor layer between the first electrode and the second electrode; a second oxide semiconductor layer separated from the first oxide semiconductor layer in a second direction perpendicular to a first direction connecting the first electrode and the second electrode; and a gate electrode surrounding the first oxide semiconductor layer and the second oxide semiconductor layer and extending in the second direction. The gate electrode includes a first portion and a second portion. The first portion faces the first oxide semiconductor layer and is in contact with the gate insulating layer in the second direction, and has a first length in the first direction. The second portion is away from the first oxide semiconductor layer in the second direction and has a second length in the first direction smaller than the first length.

### CROSS-REFERENCE TO RELATED APPLICATION

This application is based upon and claims the benefit of priority from Japanese Patent Application No. 2024-164458, filed on Sep. 20, 2024, the entire contents of which are incorporated herein by reference.

### FIELD

Embodiments described herein relate generally to a semiconductor device and a semiconductor memory device.

### BACKGROUND

An oxide semiconductor transistor in which a channel is formed in an oxide semiconductor layer has an excellent characteristic that the channel leakage current during off operation is very small. For this reason, for example, the oxide semiconductor transistor can be applied as a switching transistor of a memory cell in a dynamic random access memory (DRAM).

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is a schematic cross-sectional view showing an example of a method for manufacturing the semiconductor device according to the first embodiment;

FIG. 5 is a schematic cross-sectional view showing an example of the method for manufacturing the semiconductor device according to the first embodiment;

FIG. 6 is a schematic cross-sectional view showing an example of the method for manufacturing the semiconductor device according to the first embodiment;

FIG. 7 is a schematic cross-sectional view showing an example of the method for manufacturing the semiconductor device according to the first embodiment;

FIG. 8 is a schematic cross-sectional view showing an example of the method for manufacturing the semiconductor device according to the first embodiment;

FIG. 9 is a schematic cross-sectional view showing an example of the method for manufacturing the semiconductor device according to the first embodiment;

FIG. 10 is a schematic cross-sectional view showing an example of the method for manufacturing the semiconductor device according to the first embodiment;

FIG. 11 is a schematic cross-sectional view showing an example of the method for manufacturing the semiconductor device according to the first embodiment;

FIG. 12 is a schematic cross-sectional view showing an example of the method for manufacturing the semiconductor device according to the first embodiment;

FIG. 13 is a schematic cross-sectional view showing an example of the method for manufacturing the semiconductor device according to the first embodiment;

FIG. 14 is a schematic cross-sectional view showing an example of the method for manufacturing the semiconductor device according to the first embodiment;

FIG. 15 is a schematic cross-sectional view showing an example of the method for manufacturing the semiconductor device according to the first embodiment;

FIG. 16 is a schematic cross-sectional view showing an example of the method for manufacturing the semiconductor device according to the first embodiment;

FIG. 17 is a schematic cross-sectional view showing an example of the method for manufacturing the semiconductor device according to the first embodiment;

FIG. 18 is a schematic cross-sectional view showing an example of the method for manufacturing the semiconductor device according to the first embodiment;

FIG. 19 is a schematic cross-sectional view showing an example of the method for manufacturing the semiconductor device according to the first embodiment;

FIG. 20 is a schematic cross-sectional view showing an example of the method for manufacturing the semiconductor device according to the first embodiment;

FIG. 21 is a schematic cross-sectional view showing an example of the method for manufacturing the semiconductor device according to the first embodiment;

FIG. 22 is an explanatory diagram of the function and effect of the semiconductor device according to the first embodiment;

FIG. 23 is an explanatory diagram of the function and effect of the semiconductor device according to the first embodiment;

FIG. 24 is an explanatory diagram of the function and effect of the semiconductor device according to the first embodiment;

FIG. 25 is an explanatory diagram of the function and effect of the semiconductor device according to the first embodiment;

FIG. 26 is a schematic cross-sectional view of a semiconductor device according to a first modification example of the first embodiment;

FIG. 27 is a schematic cross-sectional view of a semiconductor device according to a second modification example of the first embodiment;

FIG. 28 is a schematic cross-sectional view of a semiconductor device according to a second embodiment;

FIG. 29 is a schematic cross-sectional view showing an example of a method for manufacturing the semiconductor device according to the second embodiment;

FIG. 30 is a schematic cross-sectional view of a semiconductor device according to a first modification example of the second embodiment;

FIG. 31 is a schematic cross-sectional view of a semiconductor device according to a second modification example of the second embodiment;

FIG. 32 is a schematic cross-sectional view showing an example of a method for manufacturing the semiconductor device according to the second modification example of the second embodiment;

FIG. 33 is a schematic cross-sectional view of a semiconductor device according to a third embodiment;

FIG. 34 is a schematic cross-sectional view of a semiconductor device according to a fourth embodiment;

FIG. 35 is a schematic cross-sectional view of the semiconductor device according to the fourth embodiment;

FIG. 36 is a schematic cross-sectional view of a semiconductor device according to a fifth embodiment;

FIG. 37 is a schematic cross-sectional view of the semiconductor device according to the fifth embodiment;

FIG. 38 is a schematic cross-sectional view showing an example of a method for manufacturing the semiconductor device according to the fifth embodiment;

FIG. 39 is a schematic cross-sectional view showing an example of the method for manufacturing the semiconductor device according to the fifth embodiment;

FIG. 40 is a schematic cross-sectional view showing an example of the method for manufacturing the semiconductor device according to the fifth embodiment;

FIG. 41 is a schematic cross-sectional view showing an example of the method for manufacturing the semiconductor device according to the fifth embodiment;

FIG. 42 is a schematic cross-sectional view showing an example of the method for manufacturing the semiconductor device according to the fifth embodiment;

FIG. 43 is a schematic cross-sectional view showing an example of the method for manufacturing the semiconductor device according to the fifth embodiment;

FIG. 44 is a schematic cross-sectional view showing an example of the method for manufacturing the semiconductor device according to the fifth embodiment;

FIG. 45 is an equivalent circuit diagram of a semiconductor memory device according to a sixth embodiment; and

FIG. 46 is a schematic cross-sectional view of the semiconductor memory device according to the sixth embodiment.

FIG. 47 is a schematic cross-sectional view of a semiconductor device according to a seventh embodiment.

FIG. 48 is a schematic cross-sectional view of a semiconductor device according to a modification example of the seventh embodiment.

### DETAILED DESCRIPTION

A semiconductor device of embodiments includes: a first electrode; a second electrode; a first oxide semiconductor layer provided between the first electrode and the second electrode; a third electrode; a fourth electrode; a second oxide semiconductor layer provided between the third electrode and the fourth electrode, the second oxide semiconductor layer being separated from the first oxide semiconductor layer in a second direction perpendicular to a first direction connecting the first electrode and the second electrode; a gate electrode surrounding the first oxide semiconductor layer and the second oxide semiconductor layer and extending in the second direction; and a gate insulating layer provided between the gate electrode and the first oxide semiconductor layer. The gate electrode includes a first portion and a second portion. The first portion faces the first oxide semiconductor layer and is in contact with the gate insulating layer in the second direction, and has a first length in the first direction. The second portion is away from the first oxide semiconductor layer in the second direction by a distance corresponding to half a distance between the first oxide semiconductor layer and the second oxide semiconductor layer, and has a second length in the first direction. The first length is larger than the second length.

Hereinafter, embodiments will be described with reference to the diagrams. In addition, in the following description, the same or similar members and the like are denoted by the same reference numerals, and the description of the members and the like once described may be omitted as appropriate.

In addition, in this specification, the terms “on”, “below”, “upper”, and “lower” may be used for convenience. “On”, “below”, “upper”, and “lower” are terms that only indicate the relative positional relationship in the diagrams, but are not terms that define the positional relationship with respect to gravity.

The qualitative analysis and quantitative analysis of the chemical composition of members forming the semiconductor device and the semiconductor memory device in this specification can be performed by, for example, secondary ion mass spectrometry (SIMS), energy dispersive X-ray spectroscopy (EDX), and Rutherford back-scatting spectroscopy (RBS). In addition, when measuring the thickness of each member forming the semiconductor device and the semiconductor memory device, a distance between members, a crystal particle size, and the like, it is possible to use, for example, a transmission electron microscope (TEM). In addition, for the identification of the constituent materials of members forming the semiconductor device and the semiconductor memory device and the measurement of the abundance ratio of the constituent materials, for example, X-ray photoelectron spectroscopy (XPS), hard X-ray photoelectron spectroscopy (HAXPES), and electron energy loss spectroscopy (EELS) can be used.

In this specification, “metal” is a general term for substances that exhibit metallic properties, and for example, metal compounds such as metal nitrides and metal carbides that exhibit metallic properties are also included in the scope of “metal”.

### First Embodiment

A semiconductor device according to a first embodiment includes: a first electrode; a second electrode; a first oxide semiconductor layer provided between the first electrode and the second electrode; a third electrode; a fourth electrode; a second oxide semiconductor layer provided between the third electrode and the fourth electrode and provided so as to be separated from the first oxide semiconductor layer in a second direction perpendicular to a first direction connecting the first electrode and the second electrode to each other; a gate electrode surrounding the first oxide semiconductor layer and the second oxide semiconductor layer and extending in the second direction; and a gate insulating layer provided between the gate electrode and the first oxide semiconductor layer. The gate electrode includes a first portion and a second portion. The first portion faces the first oxide semiconductor layer and is in contact with the gate insulating layer in the second direction, and has a first length in the first direction. The second portion is away from the first oxide semiconductor layer in the second direction by a distance corresponding to half a distance between the first oxide semiconductor layer and the second oxide semiconductor layer, and has a second length in the first direction. The first length is larger than the second length.

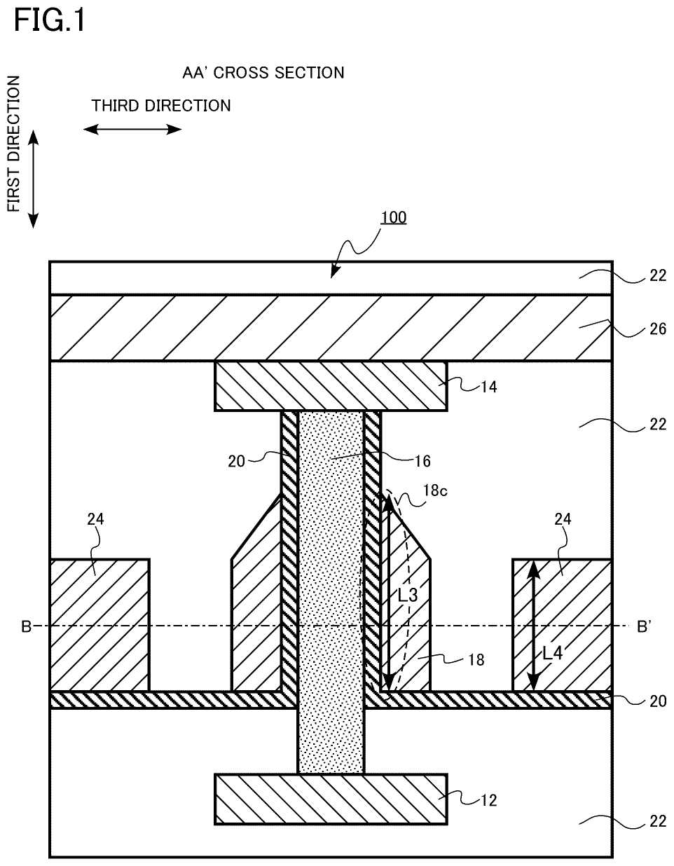

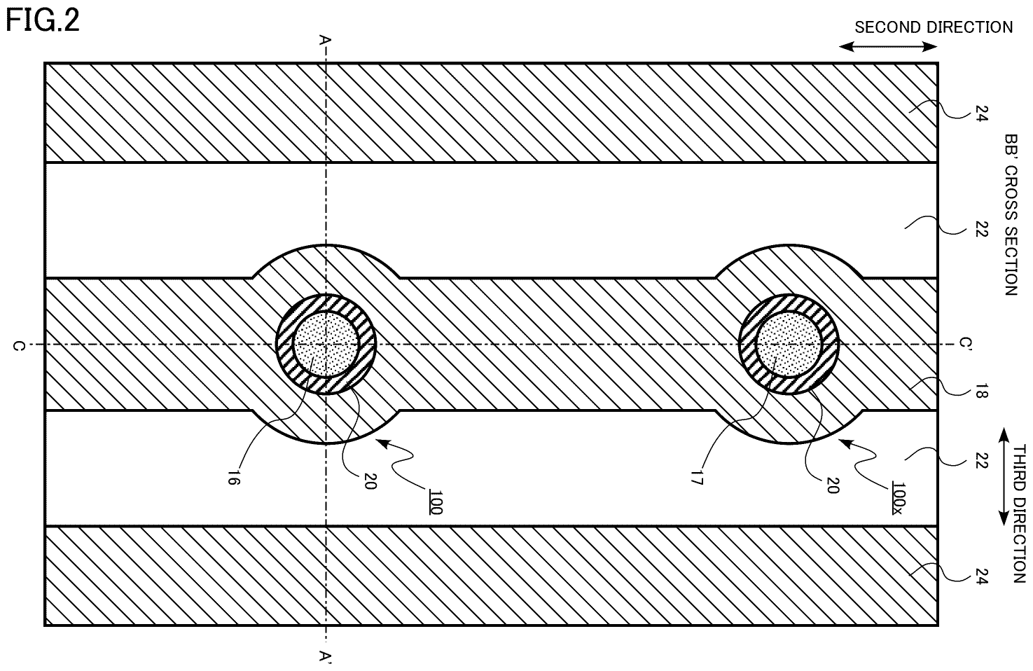

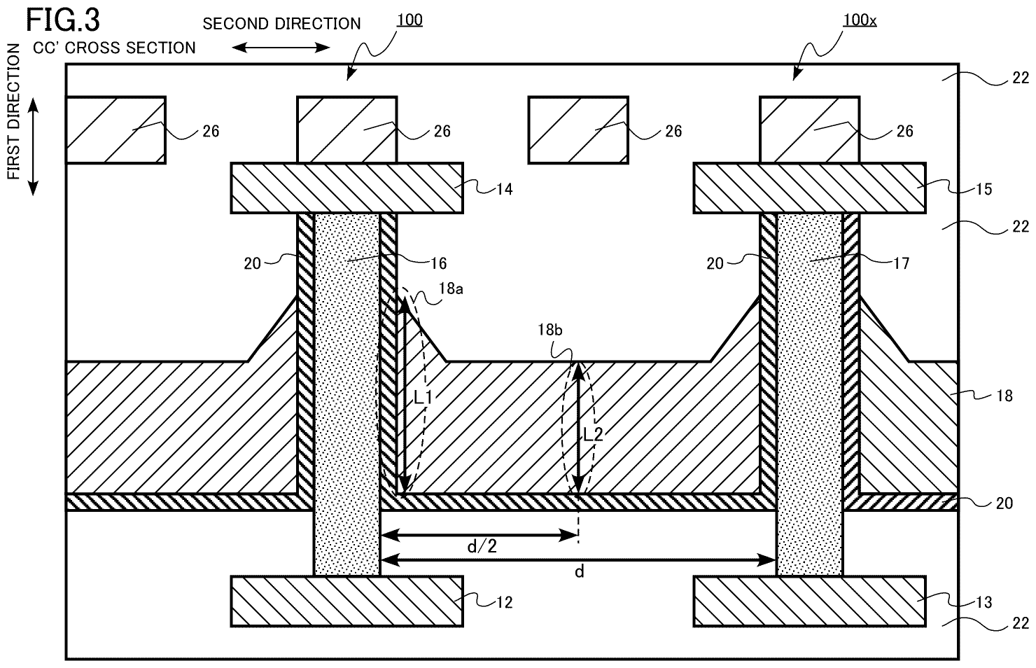

FIGS. 1, 2, and 3 are schematic cross-sectional views of the semiconductor device according to the first embodiment. FIG. 1 is a cross-sectional view taken along the line AA′ of FIG. 2. FIG. 2 is a cross-sectional view taken along the line BB′ of FIG. 1. FIG. 3 is a cross-sectional view taken along the line CC′ of FIG. 2.

In FIG. 1, the vertical direction is referred to as a first direction. In FIG. 1, the horizontal direction is referred to as a third direction. The third direction is perpendicular to the first direction. In FIG. 3, the horizontal direction is referred to as a second direction. The second direction is a direction perpendicular to the first direction and the third direction. The first direction is a direction connecting a lower electrode 12 and an upper electrode 14 to each other.

The semiconductor device according to the first embodiment includes a transistor 100. The transistor 100 is an oxide semiconductor transistor in which a channel is formed in the oxide semiconductor. In the transistor 100, a gate electrode is provided so as to surround an oxide semiconductor layer in which a channel is formed. The transistor 100 is a so-called surrounding gate transistor (SGT). The transistor 100 is a so-called vertical transistor.

The transistor 100 includes the lower electrode 12, the upper electrode 14, an oxide semiconductor layer 16, a gate electrode 18, a gate insulating layer 20, and an interlayer insulating layer 22.

The lower electrode 12 is an example of the first electrode. The upper electrode 14 is an example of the second electrode. The oxide semiconductor layer 16 is an example of the first oxide semiconductor layer.

The semiconductor device according to the first embodiment includes a transistor 100x, a first wiring layer 24, and a second wiring layer 26 in addition to the transistor 100.

The transistor 100x includes a lower electrode 13, an upper electrode 15, an oxide semiconductor layer 17, the gate electrode 18, the gate insulating layer 20, and the interlayer insulating layer 22.

The lower electrode 13 is an example of the third electrode. The upper electrode 15 is an example of the fourth electrode. The oxide semiconductor layer 17 is an example of the second oxide semiconductor layer.

The transistor 100x is provided in the second direction of the transistor 100. The oxide semiconductor layer 17 is provided so as to be separated from the oxide semiconductor layer 16 in the second direction.

The transistor 100x has the same configuration as the transistor 100. Hereinafter, detailed description of the transistor 100x will be omitted.

The lower electrode 12 is provided below the oxide semiconductor layer 16. The lower electrode 12 is electrically connected to the oxide semiconductor layer 16. The lower electrode 12 is in contact with, for example, the oxide semiconductor layer 16. The lower electrode 12 functions as a source electrode or a drain electrode of the transistor 100.

The lower electrode 12 is a conductor. The lower electrode 12 contains, for example, an oxide conductor. The lower electrode 12 is, for example, an oxide conductor layer.

The lower electrode 12 contains, for example, indium (In), tin (Sn), and oxygen (O). The lower electrode 12 contains, for example, indium tin oxide. The lower electrode 12 is, for example, an indium tin oxide layer.

The lower electrode 12 contains, for example, tin (Sn) and oxygen (O). The lower electrode 12 contains, for example, tin oxide. The lower electrode 12 is, for example, a tin oxide layer.

The lower electrode 12 contains, for example, a metal. The lower electrode 12 is, for example, a metal layer.

The lower electrode 12 contains, for example, tungsten (W), molybdenum (Mo), copper (Cu), aluminum (Al), titanium (Ti), or tantalum (Ta). The lower electrode 12 is, for example, a tungsten layer, a molybdenum layer, a copper layer, an aluminum layer, a titanium layer, or a tantalum layer.

The lower electrode 12 may have, for example, a stacked structure of a plurality of conductors. The lower electrode 12 has, for example, a stacked structure of an oxide conductor layer and a metal layer. For example, the surface of the lower electrode 12 on the oxide semiconductor layer 16 side is an oxide conductor layer.

The upper electrode 14 is provided on the oxide semiconductor layer 16. The upper electrode 14 is electrically connected to the oxide semiconductor layer 16. The upper electrode 14 is in contact with, for example, the oxide semiconductor layer 16. The upper electrode 14 functions as a source electrode or a drain electrode of the transistor 100.

The upper electrode 14 is a conductor. The upper electrode 14 contains, for example, an oxide conductor. The upper electrode 14 is, for example, an oxide conductor layer.

The upper electrode 14 contains, for example, indium (In), tin (Sn), and oxygen (O). The upper electrode 14 contains, for example, indium tin oxide. The upper electrode 14 is, for example, an indium tin oxide layer.

The upper electrode 14 contains, for example, tin (Sn) and oxygen (O). The upper electrode 14 contains, for example, tin oxide. The upper electrode 14 is, for example, a tin oxide layer.

The upper electrode 14 contains, for example, a metal. The upper electrode 14 is, for example, a metal layer.

The upper electrode 14 contains, for example, tungsten (W), molybdenum (Mo), copper (Cu), aluminum (Al), titanium (Ti), or tantalum (Ta). The upper electrode 14 is, for example, a tungsten layer, a molybdenum layer, a copper layer, an aluminum layer, a titanium layer, or a tantalum layer.

The upper electrode 14 may have, for example, a stacked structure of a plurality of conductors. The upper electrode 14 has, for example, a stacked structure of an oxide conductor layer and a metal layer. For example, the surface of the upper electrode 14 on the oxide semiconductor layer 16 side is an oxide conductor layer.

The lower electrode 12 and the upper electrode 14 are formed of, for example, the same material. For example, the lower electrode 12 and the upper electrode 14 are oxide conductors containing indium (In), tin (Sn), and oxygen (O). The lower electrode 12 and the upper electrode 14 contain, for example, indium tin oxide. The lower electrode 12 and the upper electrode 14 are, for example, indium tin oxide layers.

The oxide semiconductor layer 16 is provided between the lower electrode 12 and the upper electrode 14. The oxide semiconductor layer 16 is in contact with, for example, the lower electrode 12. The oxide semiconductor layer 16 is in contact with, for example, the upper electrode 14.

The oxide semiconductor layer 16 has a columnar shape. The oxide semiconductor layer 16 has, for example, a cylindrical shape. The oxide semiconductor layer 16 may have, for example, a rectangular prism shape.

In the oxide semiconductor layer 16, a channel serving as a current path is formed when the transistor 100 is turned on.

The oxide semiconductor layer 16 is an oxide semiconductor. The oxide semiconductor layer 16 is, for example, amorphous.

The oxide semiconductor layer 16 contains, for example, at least one element selected from a group consisting of indium (In), gallium (Ga), silicon (Si), aluminum (Al), and tin (Sn), zinc (Zn), and oxygen (O). The oxide semiconductor layer 16 contains, for example, indium (In), gallium (Ga), zinc (Zn), and oxygen (O). The oxide semiconductor layer 16 contains, for example, indium gallium zinc oxide. The oxide semiconductor layer 16 is, for example, an indium gallium zinc oxide layer.

The oxide semiconductor layer 16 contains, for example, at least one element selected from a group consisting of titanium (Ti), zinc (Zn), and tungsten (W), and oxygen (O). The oxide semiconductor layer 16 contains, for example, titanium oxide, zinc oxide, or tungsten oxide. The oxide semiconductor layer 16 is, for example, a titanium oxide layer, a zinc oxide layer, or a tungsten oxide layer.

The oxide semiconductor layer 16 has, for example, a chemical composition different from the chemical composition of the lower electrode 12 and the chemical composition of the upper electrode 14.

The oxide semiconductor layer 16 includes oxygen vacancies. The oxygen vacancies in the oxide semiconductor layer 16 function as donors.

The length of the oxide semiconductor layer 16 in the first direction is, for example, equal to or more than 80 nm and equal to or less than 200 nm. The length of the oxide semiconductor layer 16 in the second direction is, for example, equal to or more than 20 nm and equal to or less than 100 nm.

The gate electrode 18 surrounds the oxide semiconductor layer 16 and the oxide semiconductor layer 17. The gate electrode 18 is provided so that the position coordinates of the gate electrode 18 in the first direction are a value between the position coordinates of the lower electrode 12 and the position coordinates of the upper electrode 14 in the first direction.

As shown in FIG. 2, the gate electrode 18 extends in the second direction perpendicular to the first direction.

The length of the gate electrode 18 in the first direction in a portion around the oxide semiconductor layer 16 that is in contact with the gate insulating layer 20 is larger than the length of the gate electrode 18 in the first direction in other portions away from the oxide semiconductor layer 16 in the second direction.

As shown in FIG. 3, the gate electrode 18 includes a first portion 18a and a second portion 18b. The first portion 18a is a portion that faces the oxide semiconductor layer 16 and is in contact with the gate insulating layer 20 in the second direction. The first portion 18a has a first length (L1 in FIG. 3) in the first direction. In addition, the second portion 18b is a portion that is away from the oxide semiconductor layer 16 in the second direction by a distance (d/2 in FIG. 3) that is half the distance (d in FIG. 3) between the oxide semiconductor layer 16 and the oxide semiconductor layer 17. The second portion 18b has a second length (L2 in FIG. 3) in the first direction. The first length L1 is larger than the second length L2.

In addition, as shown in FIG. 1, the gate electrode 18 includes a third portion 18c. The third portion 18c is a portion that faces the oxide semiconductor layer 16 and is in contact with the gate insulating layer 20 in the third direction. The third portion 18c has a third length (L3 in FIG. 1) in the first direction. The third length L3 is larger than the second length L2.

The first length L1 is, for example, equal to or more than 1.2 times and equal to or less than 2 times the second length L2. The third length L3 is, for example, equal to or more than 1.2 times and equal to or less than 2 times the second length L2.

The gate electrode 18 is a conductor. The gate electrode 18 is, for example, a metal, a metal compound, or a semiconductor. The gate electrode 18 contains, for example, tungsten (W).

The length of the gate electrode 18 in the first direction is, for example, equal to or more than 20 nm and equal to or less than 100 nm.

The gate insulating layer 20 is provided between the oxide semiconductor layer 16 and the gate electrode 18. The gate insulating layer 20 is provided so as to surround the oxide semiconductor layer 16. The gate insulating layer 20 is provided between the lower electrode 12 and the upper electrode 14.

The gate insulating layer 20 is not in contact with, for example, the lower electrode 12. The gate insulating layer 20 is in contact with, for example, the upper electrode 14.

The gate insulating layer 20 is provided, for example, between the gate electrode 18 and the lower electrode 12 in the first direction. The gate insulating layer 20 is provided, for example, between the gate electrode 18 and the interlayer insulating layer 22 in the first direction. The gate insulating layer 20 is in contact with, for example, the gate electrode 18 and the interlayer insulating layer 22 in the first direction.

The gate insulating layer 20 is, for example, an oxide, a nitride, or an oxynitride. The gate insulating layer 20 contains, for example, silicon oxide, aluminum oxide, silicon nitride, aluminum nitride, or silicon oxynitride. The gate insulating layer 20 is, for example, a silicon oxide layer, an aluminum oxide layer, a silicon nitride layer, an aluminum nitride layer, or a silicon oxynitride layer.

The gate insulating layer 20 may have, for example, a stacked structure. The gate insulating layer 20 has, for example, a stacked structure of a nitride film and an oxide film. The gate insulating layer 20 has, for example, a stacked structure of a silicon nitride film and a silicon oxide film. For example, a silicon oxide film is provided between the oxide semiconductor layer 16 and a silicon nitride film. The thickness of the gate insulating layer 20 is, for example, equal to or more than 0.5 nm and equal to or less than 5 nm.

The lower electrode 12 is separated from the gate insulating layer 20 in the first direction, for example. In the first direction, for example, the interlayer insulating layer 22 is provided between the lower electrode 12 and the gate insulating layer 20.

The first wiring layer 24 extends in the second direction. The first wiring layer 24 is provided adjacent to the gate electrode 18 in the third direction. For example, the gate electrode 18 is interposed between two first wiring layers 24 in the third direction.

The first wiring layer 24 contains the same material as the gate electrode 18. The first wiring layer 24 is formed of the same material as the gate electrode 18. The first wiring layer 24 is formed, for example, at the same time as the gate electrode 18.

A fourth length (L4 in FIG. 1) of the first wiring layer 24 in the first direction in a cross section parallel to the first direction and the third direction and including the oxide semiconductor layer 16 as shown in FIG. 1 is shorter than the first length (L1 in FIG. 3) of the gate electrode 18. In addition, the fourth length L4 of the first wiring layer 24 is shorter than the third length (L3 in FIG. 1) of the gate electrode 18. In addition, the fourth length L4 of the first wiring layer 24 is approximately the same as the second length (L2 in FIG. 3) of the gate electrode 18.

On the lower surface of the first wiring layer 24, for example, the gate insulating layer 20 is provided. The gate insulating layer 20 is provided between the first wiring layer 24 and the interlayer insulating layer 22. The gate insulating layer 20 is in contact with the first wiring layer 24 and the interlayer insulating layer 22.

The second wiring layer 26 extends, for example, in the third direction. The second wiring layer 26 is, for example, repeatedly provided on the gate electrode 18 and the first wiring layer 24 in the second direction. The interlayer insulating layer 22 is provided between the second wiring layer 26 and each of the gate electrode 18 and first wiring layer 24. The second wiring layer 26 crosses, for example, the gate electrode 18 and the first wiring layer 24. A part of the second wiring layer 26 is electrically connected to the upper electrode 14, for example.

The interlayer insulating layer 22 surrounds, for example, the lower electrode 12, the upper electrode 14, the oxide semiconductor layer 16, and the gate insulating layer 20. The interlayer insulating layer 22 is provided, for example, between the lower electrode 12 and the gate electrode 18. The interlayer insulating layer 22 is provided, for example, between the upper electrode 14 and the gate electrode 18. The interlayer insulating layer 22 is provided, for example, between the gate electrode 18 and the first wiring layer 24.

The interlayer insulating layer 22 is an insulator. The interlayer insulating layer 22 is, for example, an oxide, a nitride, or an oxynitride. The interlayer insulating layer 22 contains, for example, silicon (Si) and oxygen (O). The interlayer insulating layer 22 contains, for example, silicon oxide. The interlayer insulating layer 22 is, for example, a silicon oxide. The interlayer insulating layer 22 contains, for example, silicon (Si) and nitrogen (N). The interlayer insulating layer 22 contains, for example, silicon nitride. The interlayer insulating layer 22 is, for example, a silicon nitride.

Next, an example of a method for manufacturing the semiconductor device according to the first embodiment will be described.

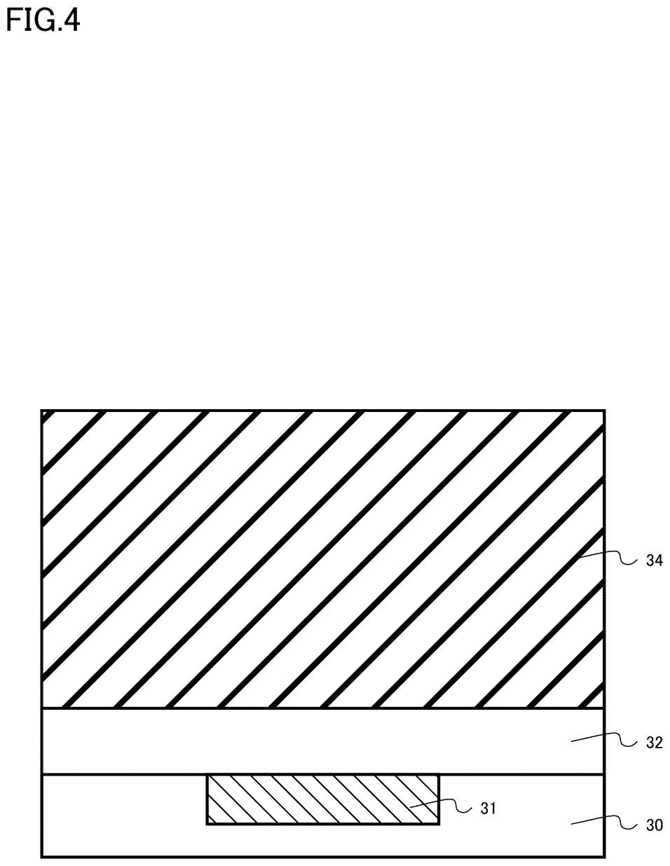

FIGS. 4 to 21 are schematic cross-sectional views showing an example of the method for manufacturing the semiconductor device according to the first embodiment. FIGS. 4 to 21 each show a cross section corresponding to FIG. 1. FIGS. 4 to 21 are diagrams showing an example of a method for manufacturing the transistor 100.

Hereinafter, a case where the lower electrode 12 of the transistor 100 is an indium tin oxide layer, the upper electrode 14 is an indium tin oxide layer, the oxide semiconductor layer 16 is an indium gallium zinc oxide layer, the gate electrode 18 is a tungsten layer, the gate insulating layer 20 is a silicon oxide layer, and the interlayer insulating layer 22 is a silicon oxide layer will be described as an example.

First, a first silicon oxide film 32 and a first silicon nitride film 34 are formed on an indium tin oxide layer 31 formed in a silicon oxide layer 30 (FIG. 4). The first silicon oxide film 32 and the first silicon nitride film 34 are formed by using, for example, a chemical vapor deposition method (CVD method).

The silicon oxide layer 30 finally becomes the interlayer insulating layer 22. The indium tin oxide layer 31 finally becomes the lower electrode 12. A part of the first silicon oxide film 32 finally becomes the interlayer insulating layer 22.

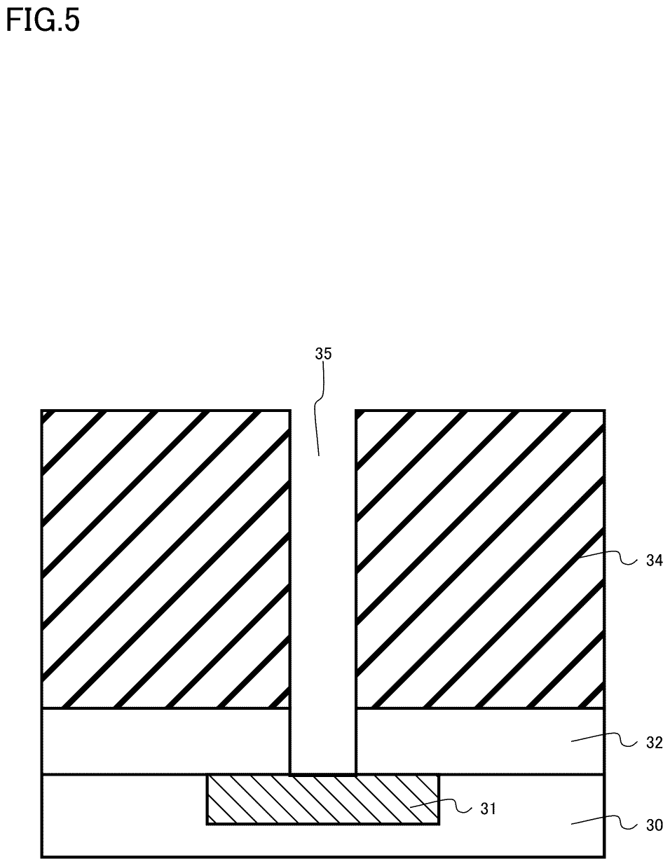

Then, the first silicon nitride film 34 and the first silicon oxide film 32 are etched to form a first opening 35 (FIG. 5). The first opening 35 is formed by using, for example, a lithography method and a reactive ion etching method (RIE method).

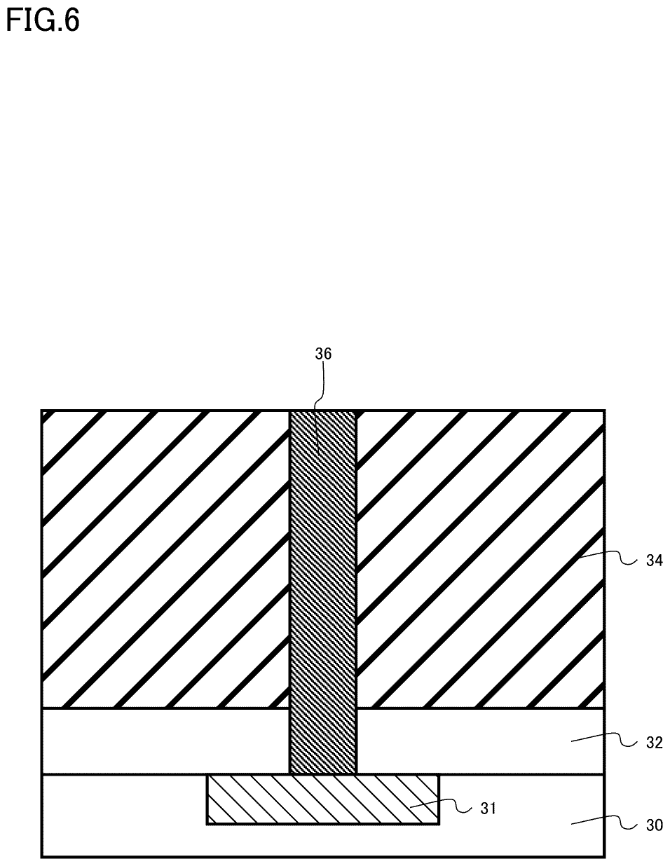

Then, the first opening 35 is filled with an amorphous silicon film 36 (FIG. 6). The amorphous silicon film 36 is formed by, for example, deposition using a CVD method and planarization processing using a chemical mechanical polishing method (CMP method).

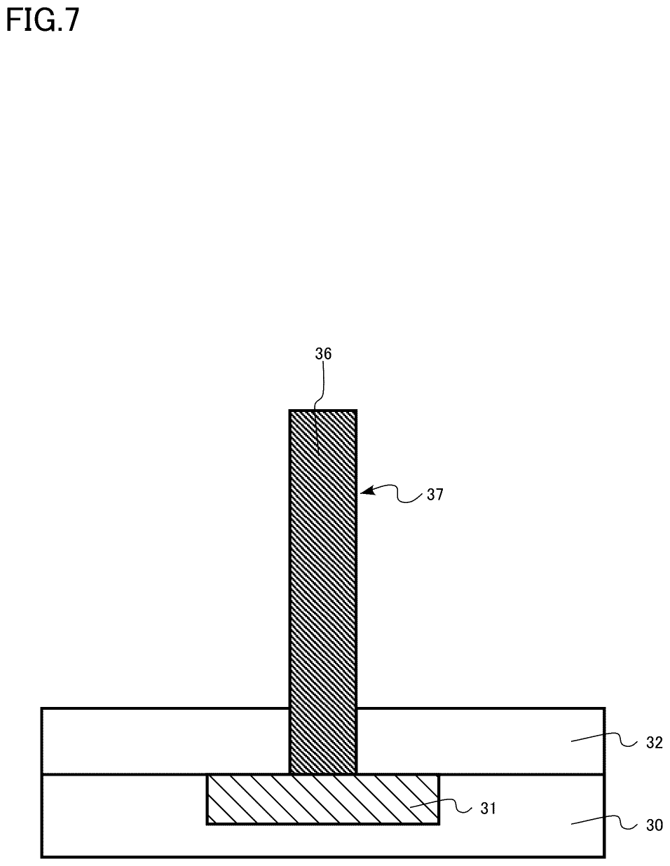

Then, the first silicon nitride film 34 is etched to expose the amorphous silicon film 36 (FIG. 7). The exposed amorphous silicon film 36 forms a pillar 37.

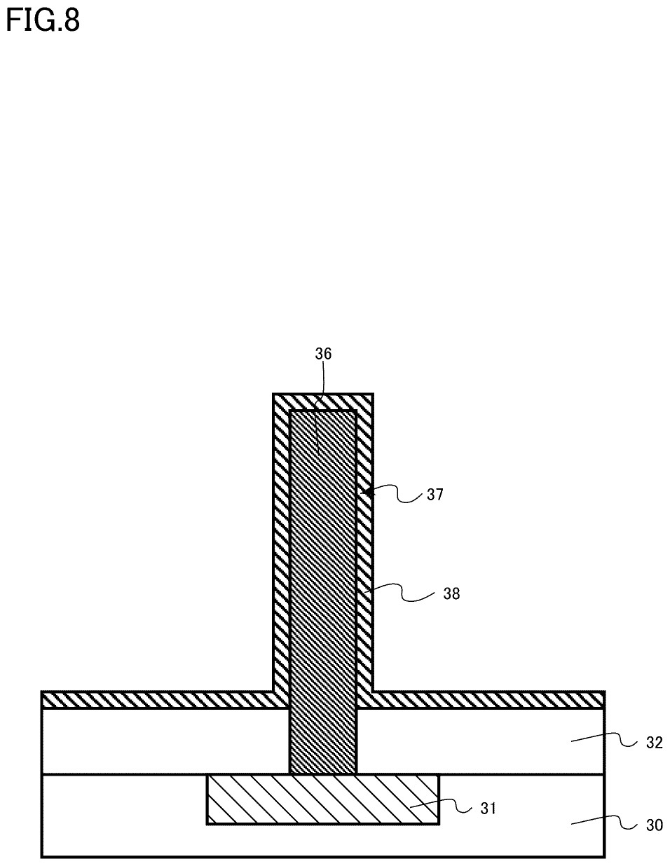

Then, the pillar 37 is covered with a second silicon oxide film 38 (FIG. 8). The second silicon oxide film 38 is formed by using, for example, a CVD method. A part of the second silicon oxide film 38 finally becomes the gate insulating layer 20.

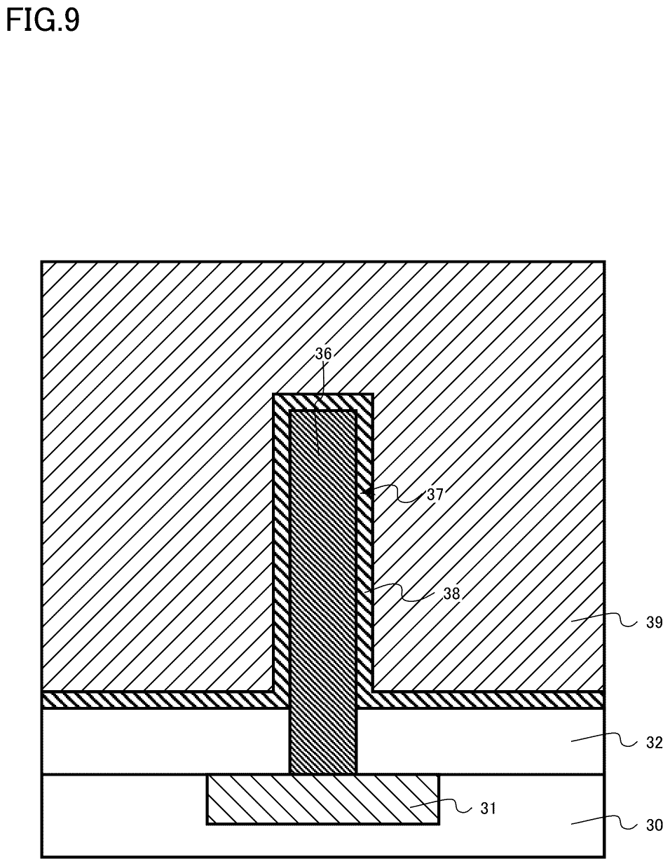

Then, the pillar 37 is covered with a tungsten film 39 (FIG. 9). The tungsten film 39 is formed by using, for example, a CVD method. A part of the tungsten film 39 finally becomes the gate electrode 18 and the first wiring layer 24.

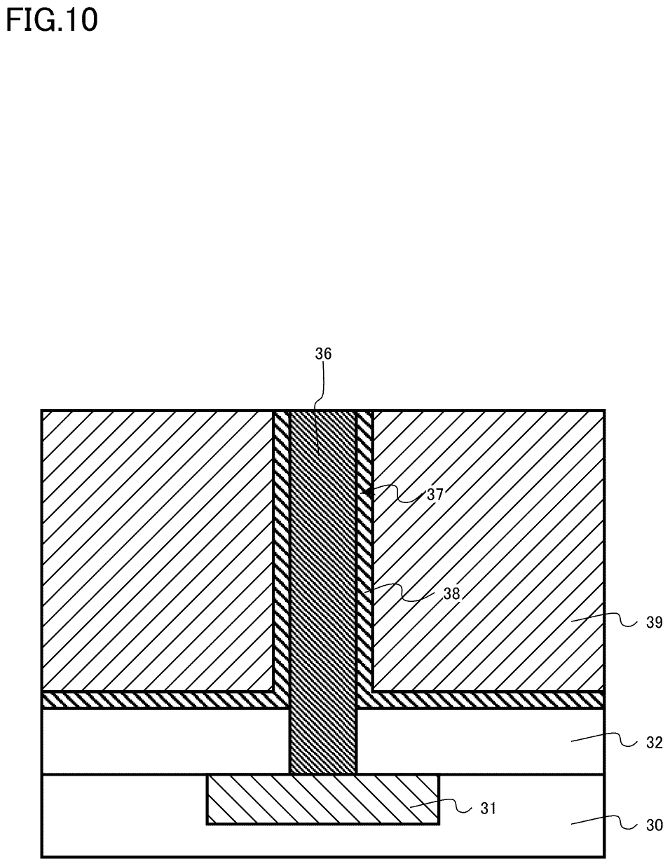

Then, the upper surface of the tungsten film 39 is planarized (FIG. 10). The tungsten film 39 is planarized by using a CMP method. The upper surface of the pillar 37 is exposed.

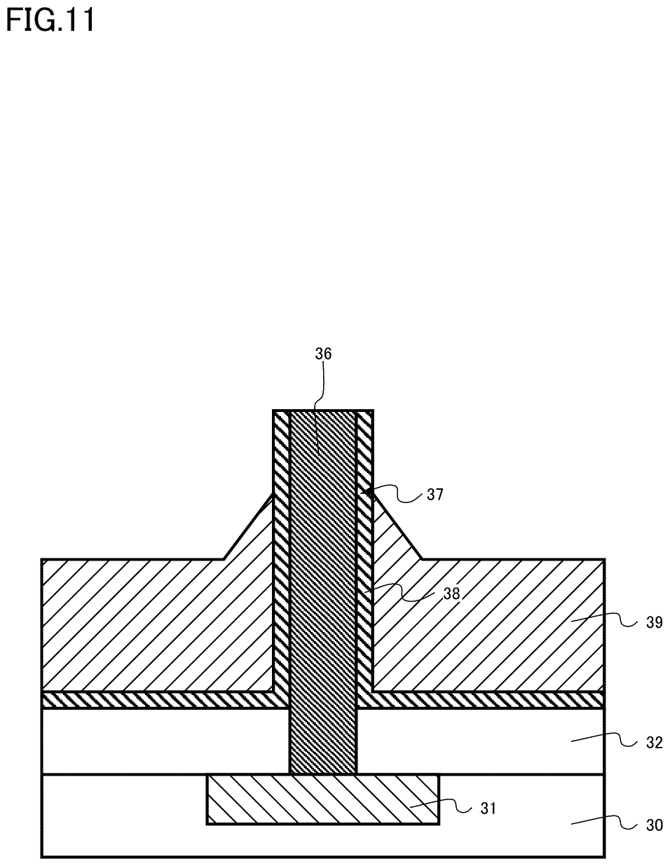

Then, a part of the tungsten film 39 is etched to expose a part of the second silicon oxide film 38 on the side surfaces of the pillar 37 (FIG. 11). At this time, the tungsten film 39 is etched so that the tungsten film 39 around the pillar 37 remains thicker than the other portions.

For example, by performing isotropic dry etching, the tungsten film 39 around the pillar 37 can be left thicker than the other portions.

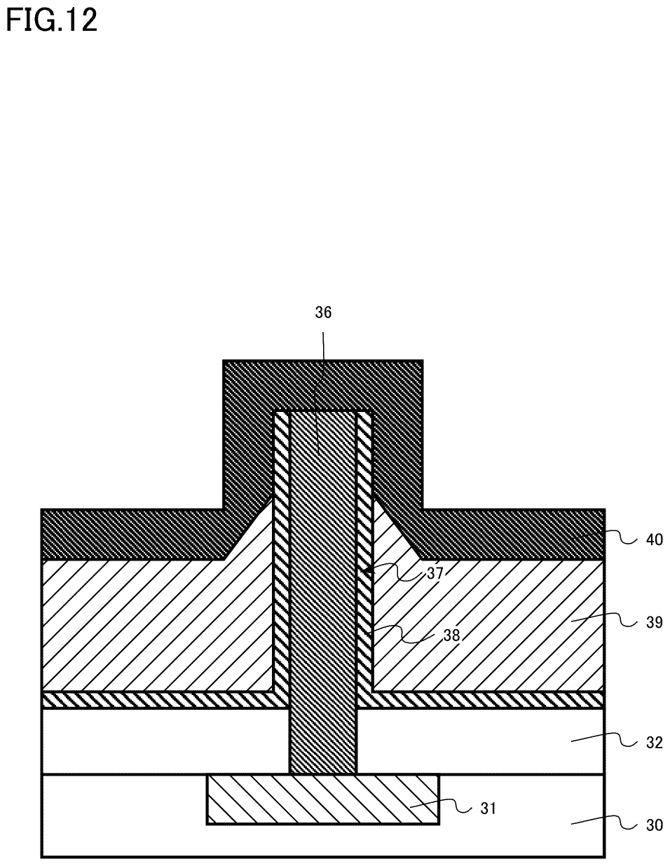

Then, the pillar 37 is covered with a second silicon nitride film 40 (FIG. 12). The second silicon nitride film 40 is formed by using, for example, a CVD method.

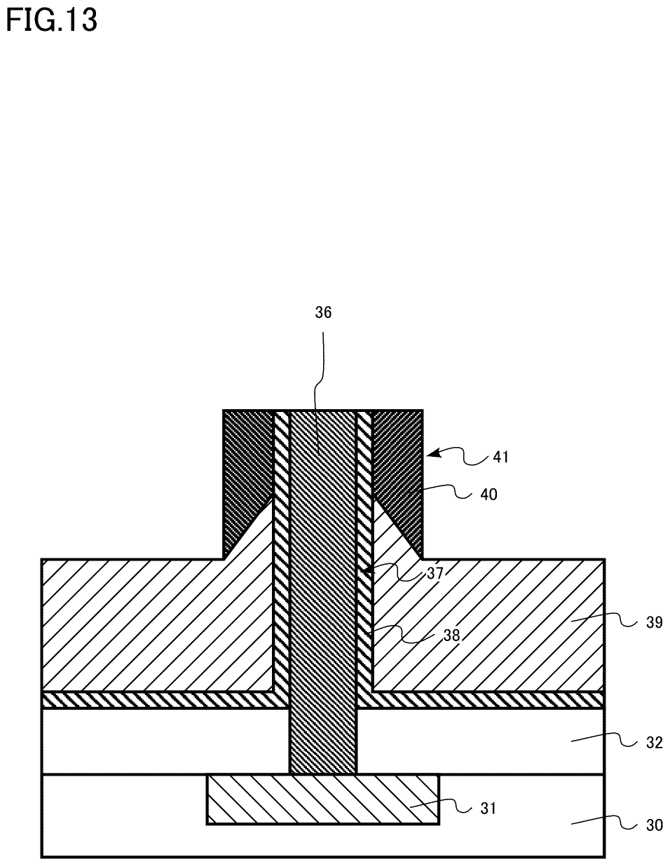

Then, the second silicon nitride film 40 is etched to form sidewalls 41 on the side surfaces of the pillar 37 (FIG. 13). The sidewalls 41 are formed by using, for example, an RIE method.

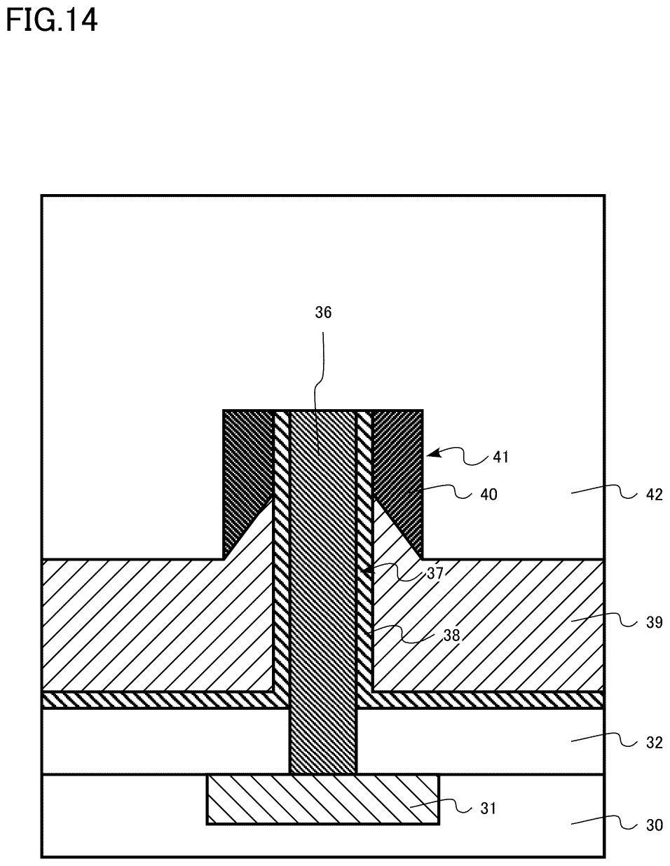

Then, the pillar 37 and the sidewalls 41 are covered with a third silicon oxide film 42 (FIG. 14). The third silicon oxide film 42 is formed by using, for example, a CVD method.

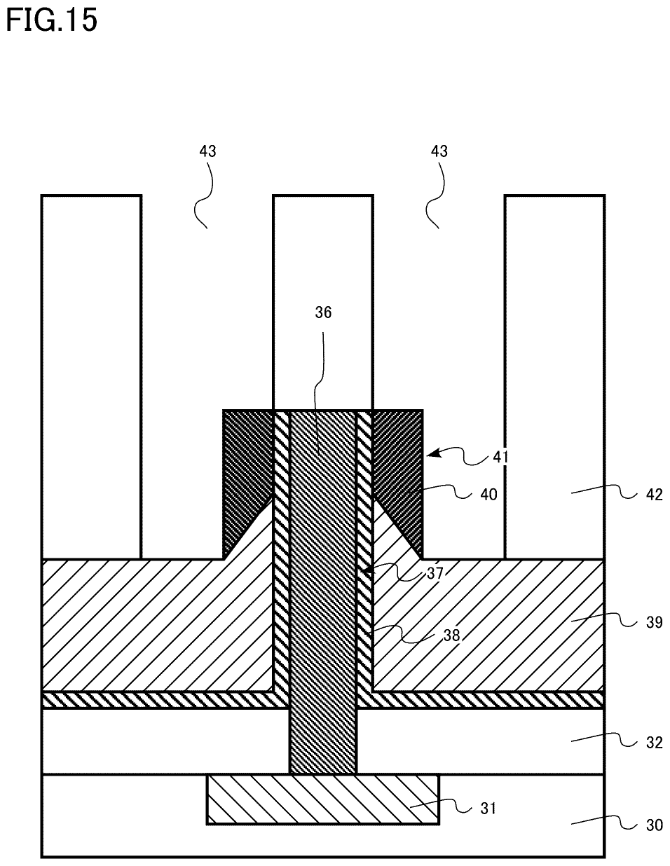

Then, the third silicon oxide film 42 is etched to form a second opening 43 where the sidewalls 41 and the tungsten film 39 are exposed (FIG. 15). The second opening 43 is formed by using a lithography method and an RIE method.

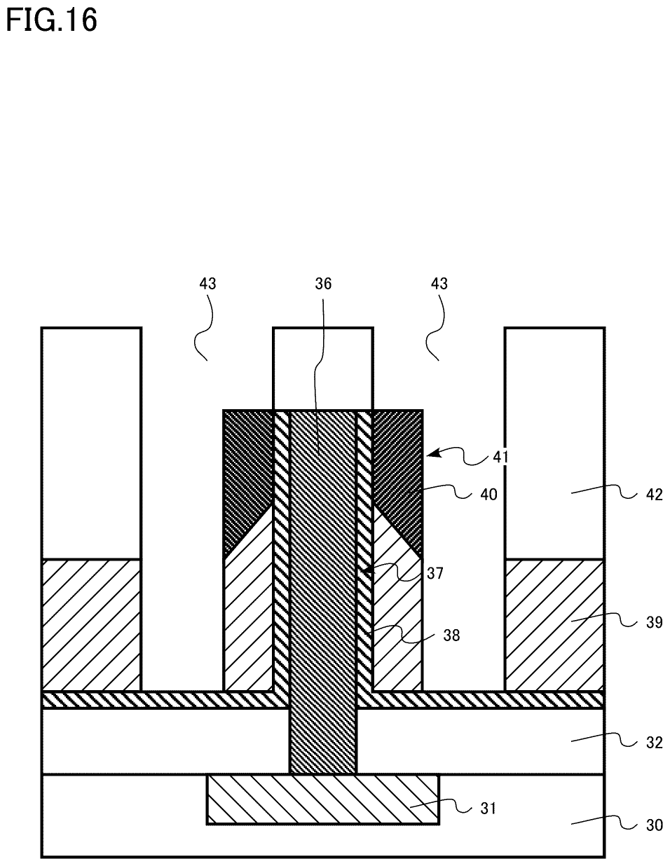

Then, the tungsten film 39 is etched using the third silicon oxide film 42 and the sidewalls 41 as a mask (FIG. 16). The tungsten film 39 is etched by using, for example, an RIE method.

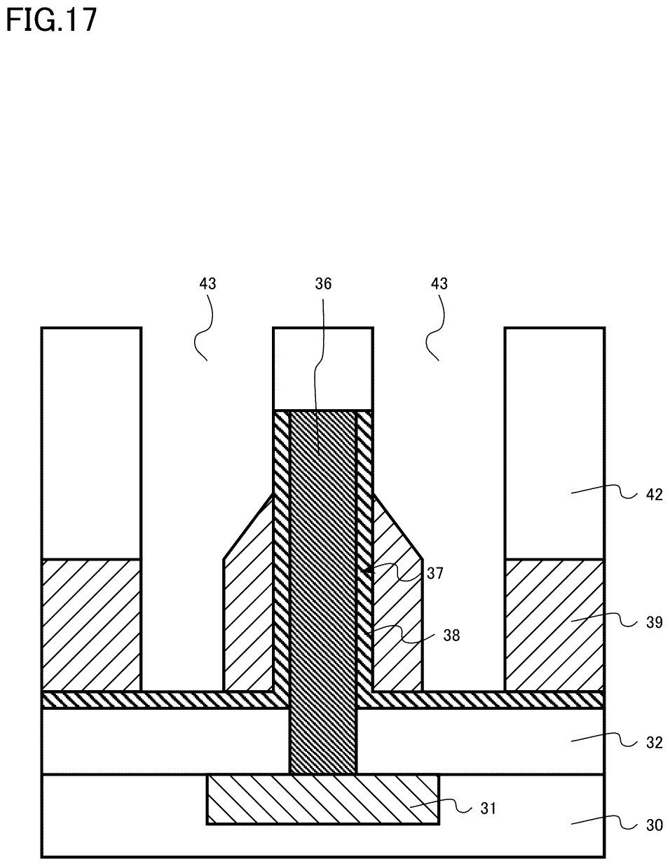

Then, the sidewalls 41 are removed (FIG. 17). The sidewalls 41 are removed by using, for example, a wet etching method.

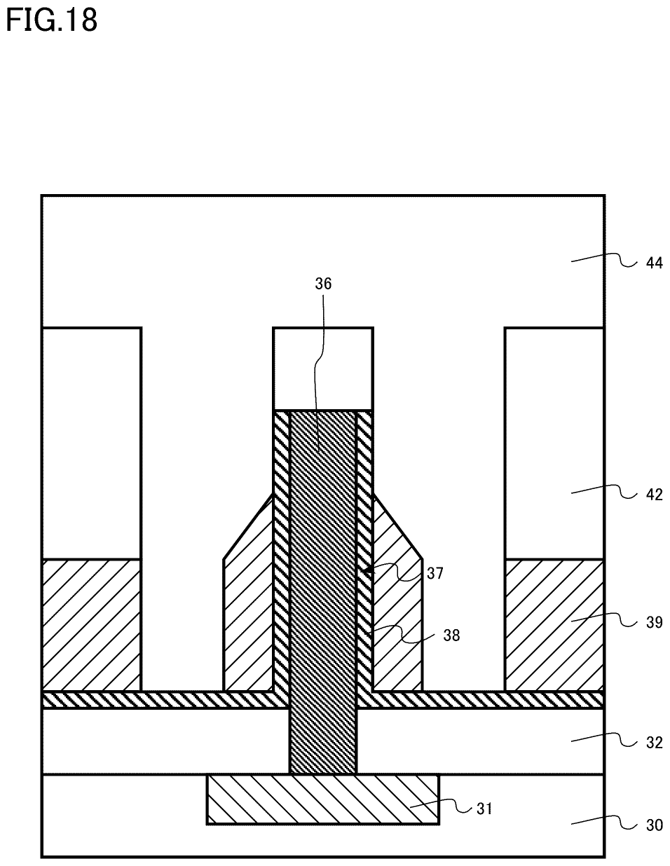

Then, the second opening 43 is filled with a fourth silicon oxide film 44 (FIG. 18). The fourth silicon oxide film 44 is formed by using, for example, a CVD method.

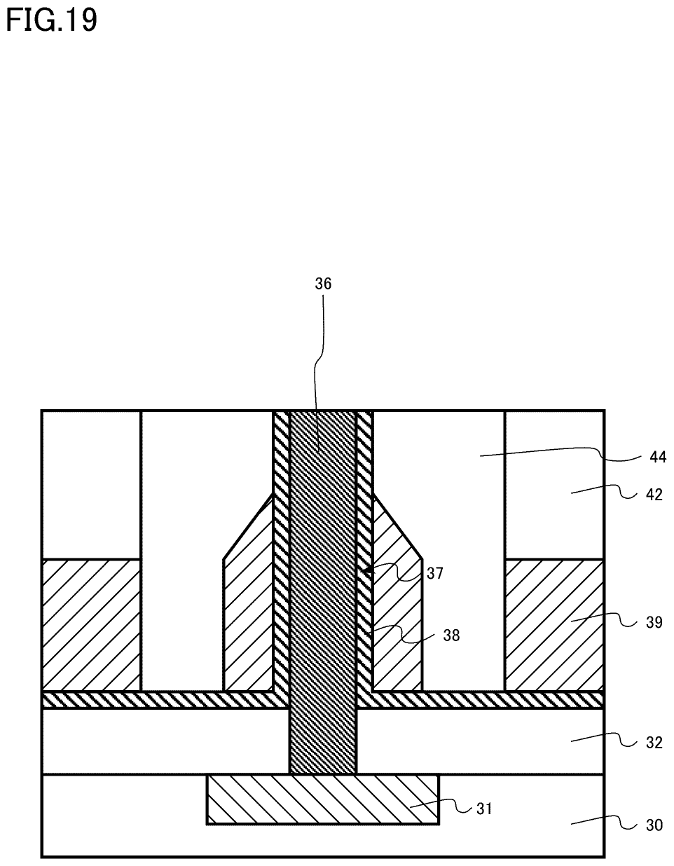

Then, the fourth silicon oxide film 44 and the third silicon oxide film 42 on the pillar 37 are removed to expose the upper surface of the pillar 37 (FIG. 19). The fourth silicon oxide film 44 and the third silicon oxide film 42 are removed by using, for example, a CMP method.

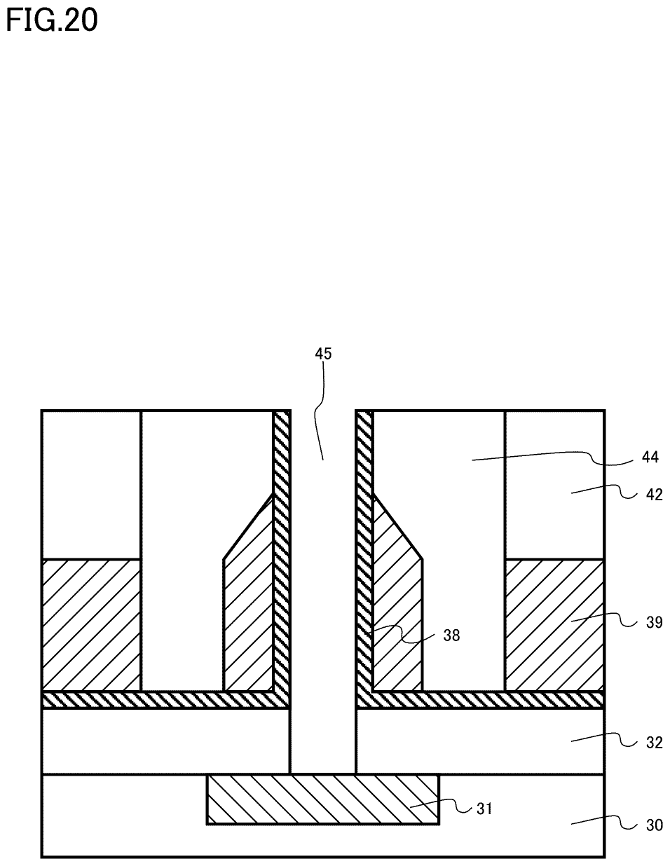

Then, the pillar 37 is removed by etching to form a third opening 45 with side surfaces on which the second silicon oxide film 38 is exposed (FIG. 20). The amorphous silicon film 36 that forms the pillar 37 is etched by using, for example, a wet etching method.

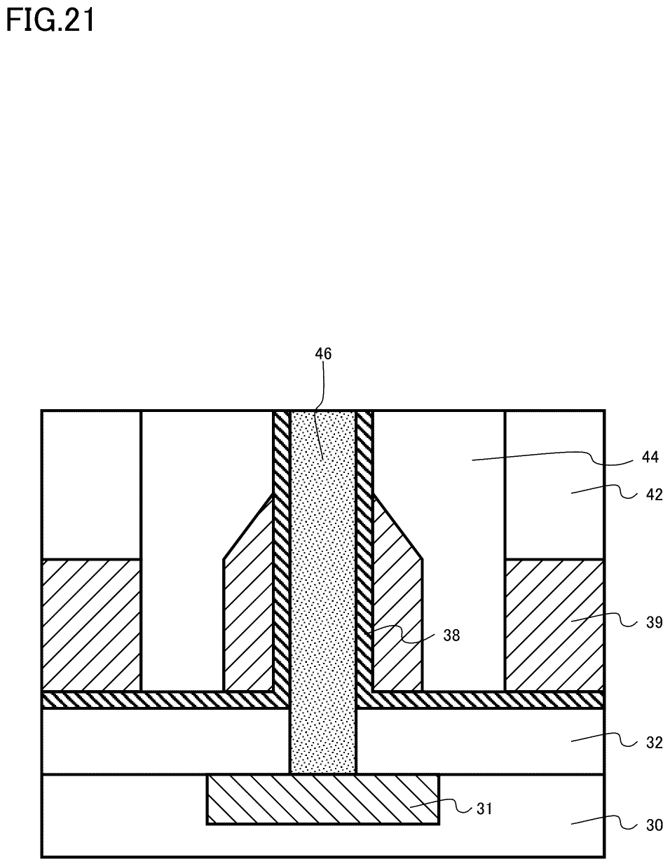

Then, the third opening 45 is filled with an indium gallium zinc oxide film 46 (FIG. 21). The indium gallium zinc oxide film 46 is formed by using a CVD method and then planarized by using a CMP method, for example. The indium gallium zinc oxide film 46 finally becomes the oxide semiconductor layer 16.

Then, the upper electrode 14 and the second wiring layer 26 that are indium tin oxide layers are formed using a known process technique.

By the manufacturing method described above, a semiconductor device including the transistor 100 shown in FIGS. 1, 2, and 3 is manufactured.

Next, the function and effect of the semiconductor device according to the first embodiment will be described.

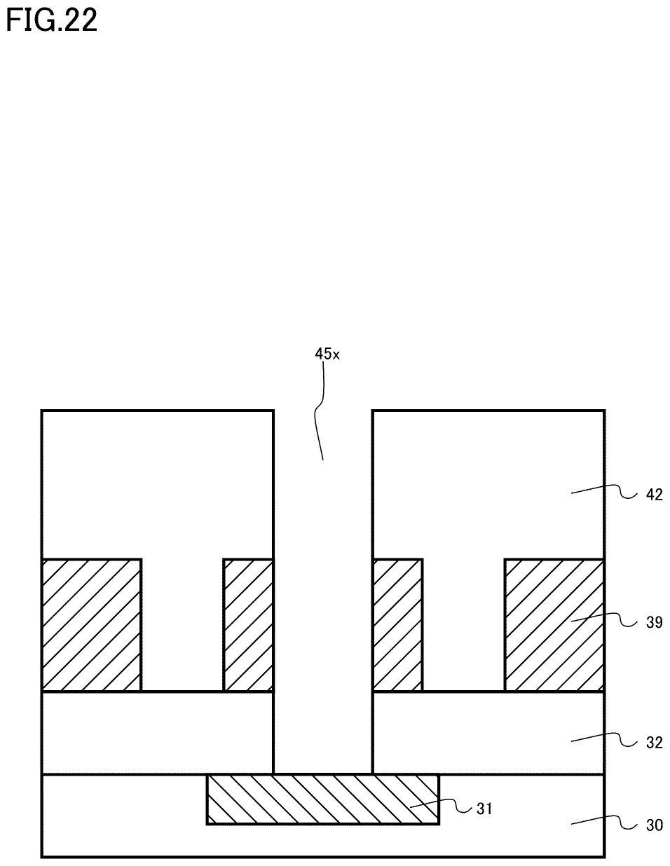

FIGS. 22 to 25 are explanatory diagrams of the function and effect of the semiconductor device according to the first embodiment. FIGS. 22 to 25 are schematic cross-sectional views showing an example of a method for manufacturing a semiconductor device according to a comparative example.

The method for manufacturing the semiconductor device according to the comparative example is different from the method for manufacturing the semiconductor device according to the first embodiment in that the second silicon oxide film 38 that becomes a gate insulating layer is formed after forming an opening 45x corresponding to the third opening 45 in the method for manufacturing the semiconductor device according to the first embodiment.

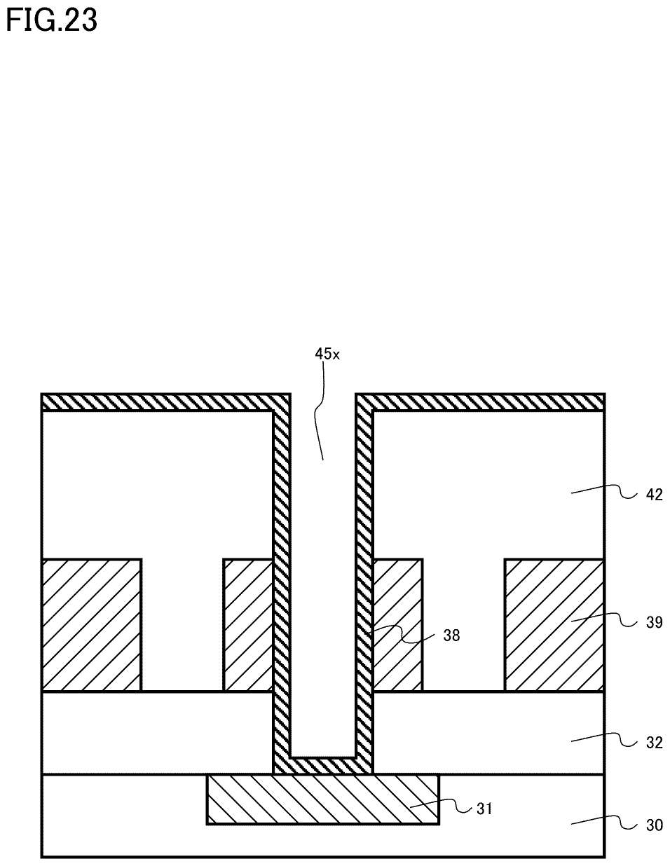

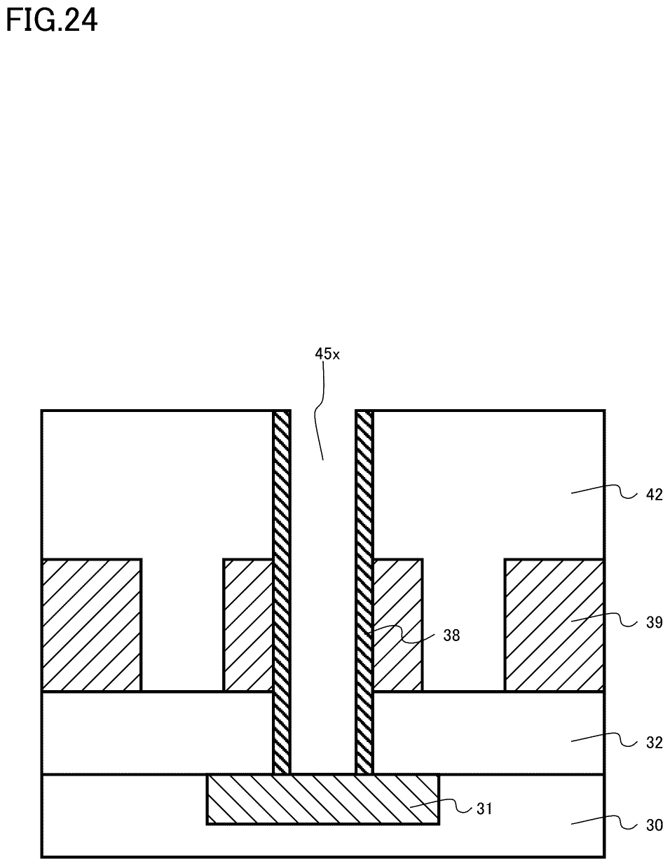

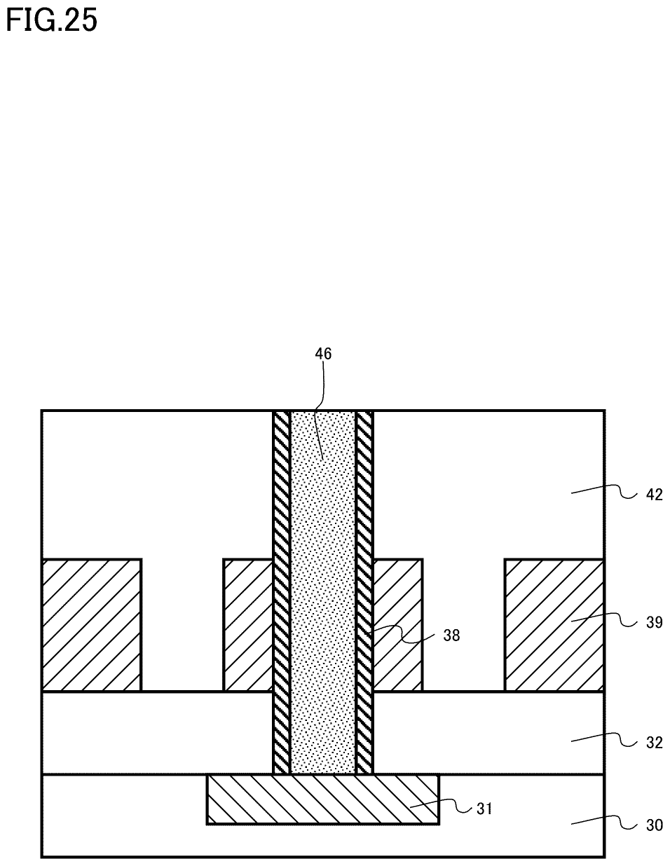

For example, as shown in FIG. 22, the opening 45x is formed so that the tungsten film 39 is exposed on its side surface and the indium tin oxide layer 31 is exposed on its bottom surface. Then, as shown in FIG. 23, the second silicon oxide film 38 that becomes a gate insulating layer is formed in the opening 45x. Then, as shown in FIG. 24, the second silicon oxide film 38 at the bottom of the opening 45x is removed by using an RIE method. Thereafter, as shown in FIG. 25, the opening 45x is filled with the indium gallium zinc oxide film 46.

The RIE method is anisotropic etching that uses ion bombardment. In the manufacturing method according to the comparative example described above, as shown in FIG. 24, when the second silicon oxide film 38 at the bottom of the opening 45x is removed by using an RIE, the surface of the second silicon oxide film 38 formed on the side surface of the opening 45x is directly exposed to ion bombardment. For this reason, processing damage remains in the second silicon oxide film 38.

The second silicon oxide film 38 finally becomes a gate insulating layer. Since processing damage remains in the gate insulating layer, the reliability of the gate insulating layer is reduced. Specifically, for example, the time-dependent dielectric breakdown characteristics (TDDB characteristics) of the gate insulating layer deteriorate.

In the method for manufacturing the semiconductor device according to the first embodiment, the pillar 37 is formed, and then the second silicon oxide film 38, which finally becomes the gate insulating layer 20, is formed on the surface of the pillar 37. As shown in FIGS. 19 and 20, when forming the third opening 45 with a bottom surface on which the indium tin oxide layer 31 is exposed, wet etching is used without using the RIE method. Therefore, the second silicon oxide film 38 that becomes the gate insulating layer 20 is not exposed to the bombardment of ions in the RIE.

Therefore, the reliability of the gate insulating layer 20 is improved compared with the method for manufacturing the semiconductor device according to the comparative example. As a result, the transistor 100 with improved reliability can be realized.

In addition, in the transistor 100 according to the first embodiment, the length of the gate electrode 18 in the first direction in a portion around the oxide semiconductor layer 16 that is in contact with the gate insulating layer 20 is large. In other words, the gate length of transistor 100 is large. Since the gate length of the transistor 100 is large, for example, the short channel effect of the transistor 100 is suppressed. Therefore, the transistor 100 with stable characteristics can be realized. In addition, since the gate length of the transistor 100 is large, for example, a high threshold voltage can be realized. Therefore, for example, the transistor 100 with a small off-leakage current can be realized.

On the other hand, in the transistor 100 according to the first embodiment, the length in the first direction of other portions away from the gate insulating layer 20 in the second direction perpendicular to the first direction, that is, portions used as a wiring layer, is kept short. Therefore, for example, compared with a case where the length in the first direction of the portion used as a wiring layer is approximately the same as the gate length of transistor 100, the inter-wiring capacitance is reduced, and accordingly, the power consumption of a semiconductor circuit using the transistor 100 can be reduced.

Specifically, for example, a distance between the gate electrode 18 and the second wiring layer 26 that is provided on the gate electrode 18 and crosses the gate electrode 18 increases. Therefore, the inter-wiring capacitance between the gate electrode 18 and the second wiring layer 26 can be reduced. In addition, the area of the surface that extends in the same direction as the gate electrode 18 and faces the adjacent first wiring layer 24 decreases. Therefore, the inter-wiring capacitance between the gate electrode 18 and the first wiring layer 24 can be reduced.

In addition, since the inter-wiring capacitance between the gate electrode 18 and the first wiring layer 24 can be reduced, it is possible to suppress the occurrence of a situation in which the electric potential of the gate electrode 18 changes due to coupling with the electric potential of the adjacent first wiring layer 24 to cause the transistor 100 to malfunction.

In addition, as can be seen from FIG. 2, the effective width of the gate electrode 18 in the third direction decreases in the vicinity of the transistor 100. In other words, the effective width of the gate electrode 18 in the third direction decreases around the oxide semiconductor layer 16. For this reason, the wiring resistance of the gate electrode 18 in the second direction increases as the effective width of the gate electrode 18 decreases around the oxide semiconductor layer 16. In the transistor 100 according to the first embodiment, the length of the gate electrode 18 in the first direction in a portion around the oxide semiconductor layer 16 that is in contact with the gate insulating layer 20 is large. For this reason, even if the effective width of the gate electrode 18 around the oxide semiconductor layer 16 decreases, an increase in the electrical resistance of the gate electrode 18 around the oxide semiconductor layer 16 can be suppressed. Therefore, an increase in the wiring resistance of the gate electrode 18 in the second direction can be suppressed.

As described above, according to the semiconductor device according to the first embodiment, it is possible to realize a semiconductor device having excellent transistor characteristics.

### First Modification Example

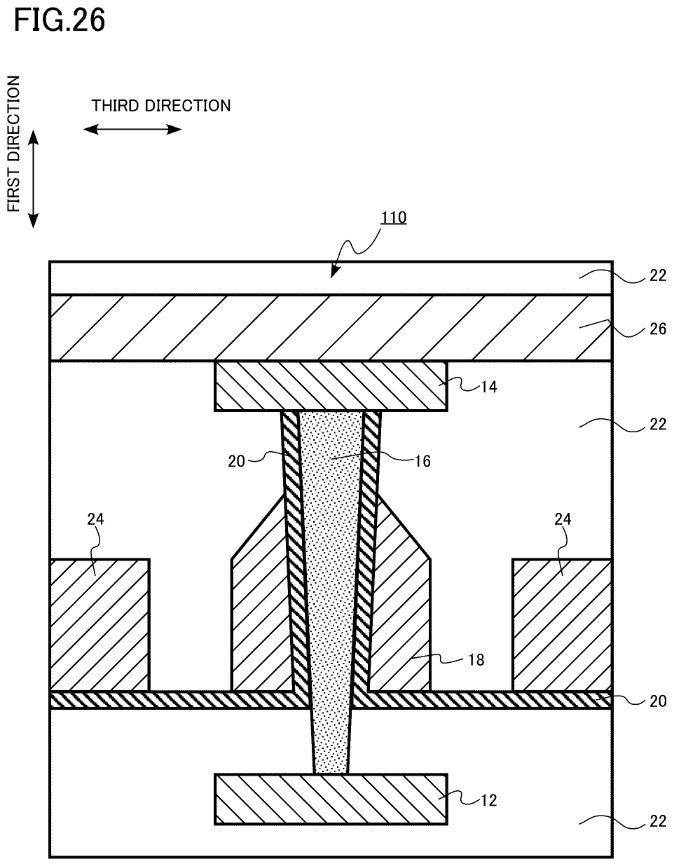

FIG. 26 is a schematic cross-sectional view of a semiconductor device according to a first modification example of the first embodiment. FIG. 26 is a diagram corresponding to FIG. 1 of the first embodiment.

A transistor 110 according to the first modification example of the first embodiment is different from the transistor 100 according to the first embodiment in that the width of the oxide semiconductor layer 16 in the third direction decreases from the upper electrode 14 toward the lower electrode 12. The transistor 110 according to the first modification example of the first embodiment is different from the transistor 100 according to the first embodiment in that the oxide semiconductor layer 16 has a so-called forward tapered shape.

### Second Modification Example

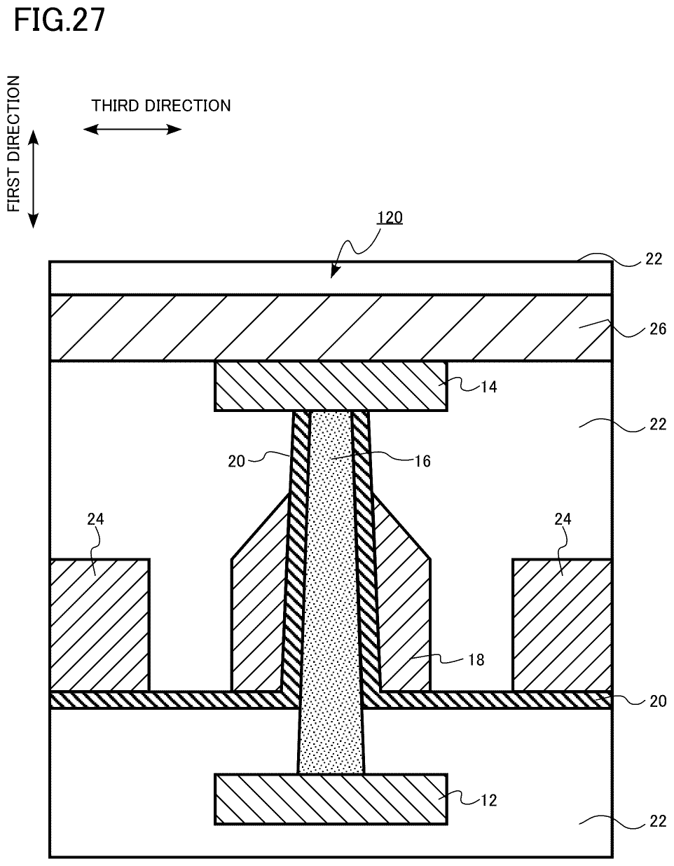

FIG. 27 is a schematic cross-sectional view of a semiconductor device according to a second modification example of the first embodiment. FIG. 27 is a diagram corresponding to FIG. 1 of the first embodiment.

A transistor 120 according to the second modification example of the first embodiment is different from the transistor 100 according to the first embodiment in that the width of the oxide semiconductor layer 16 in the third direction increases from the upper electrode 14 toward the lower electrode 12. The transistor 120 according to the second modification example of the first embodiment is different from the transistor 100 according to the first embodiment in that the oxide semiconductor layer 16 has a so-called inverse tapered shape.

As described above, according to the semiconductor devices according to the first embodiment and its modification examples, it is possible to realize a semiconductor device having excellent transistor characteristics.

### Second Embodiment

A semiconductor device according to a second embodiment is different from the semiconductor device according to the first embodiment in that an oxide semiconductor layer includes a first region and a second region provided between the first region and a second electrode, the first region is in contact with a gate insulating layer in the first direction, the second region is surrounded by the gate insulating layer, and in a cross section parallel to the first direction, the first width of the first region in a third direction perpendicular to the second direction is larger than the second width of the second region in the third direction. Hereinafter, the description of a part of the content overlapping the first embodiment may be omitted.

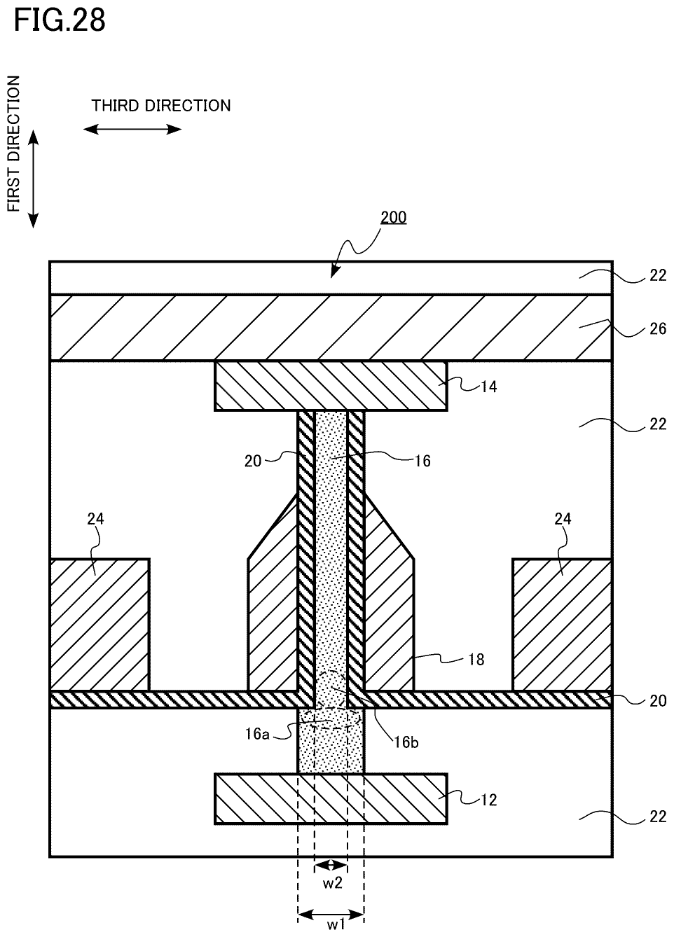

FIG. 28 is a schematic cross-sectional view of the semiconductor device according to the second embodiment. FIG. 28 is a diagram corresponding to FIG. 1 of the first embodiment.

An oxide semiconductor layer 16 of a transistor 200 according to the second embodiment includes a first region 16a and a second region 16b. The second region 16b is provided between the first region 16a and an upper electrode 14.

The first region 16a is in contact with a gate insulating layer 20 in the first direction. The second region 16b is surrounded by the gate insulating layer 20. The first region 16a is, for example, physically continuous with the second region 16b.

In a cross section parallel to the first direction, the first width (w1 in FIG. 28) of the first region 16a in the third direction perpendicular to the second direction is larger than the second width (w2 in FIG. 28) of the second region 16b in the third direction. The difference between the first width w1 of the first region 16a and the second width w2 of the second region 16b is, for example, equal to or more than 1 nm and equal to or less than 20 nm.

The oxide semiconductor layer 16 of the transistor 200 according to the second embodiment has a smaller cross-sectional area perpendicular to the first direction of the oxide semiconductor layer 16 surrounded by the gate electrode 18 than that of the transistor 100 according to the first embodiment, for example. In addition, since the oxide semiconductor layer 16 of the transistor 200 according to the second embodiment includes the first region 16a and the second region 16b, the end of the gate insulating layer 20 on the lower electrode 12 side is embedded in the oxide semiconductor layer 16.

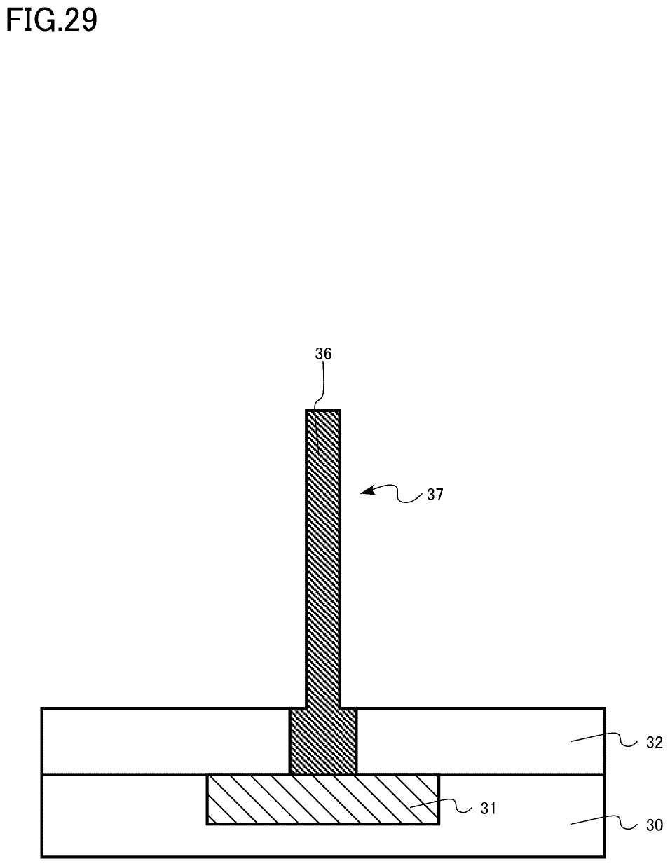

FIG. 29 is a schematic cross-sectional view showing an example of a method for manufacturing the semiconductor device according to the second embodiment.

For example, in the method for manufacturing the semiconductor device according to the first embodiment, the transistor 200 according to the second embodiment can be manufactured by adding a step of etching the pillar 37 to make the pillar 37 thin as shown in FIG. 29 after forming the pillar 37 of the amorphous silicon film 36.

According to the transistor 200 according to the second embodiment, since the cross-sectional area perpendicular to the first direction of the oxide semiconductor layer 16 surrounded by the gate electrode 18 is reduced, the strength of the electric field applied to the oxide semiconductor layer 16 by the gate electrode 18 increases. Therefore, for example, the threshold voltage of transistor 200 can be increased.

In addition, in the oxide semiconductor layer 16 of the transistor 200 according to the second embodiment, the end of the gate insulating layer 20 on the lower electrode 12 side is embedded in the oxide semiconductor layer 16. Therefore, the controllability of the electric field in the oxide semiconductor layer 16 in the vicinity of the end of the gate insulating layer 20 on the lower electrode 12 side by the gate electrode 18 is improved. Therefore, for example, an increase in on-current or a reduction in leakage current can be realized.

As described above, according to the semiconductor device according to the second embodiment, it is possible to realize a semiconductor device having excellent transistor characteristics.

### First Modification Example

A semiconductor device according to a first modification example of the second embodiment is different from the semiconductor device according to the second embodiment in that the gate insulating layer is provided between the first region and the gate electrode in the first direction.

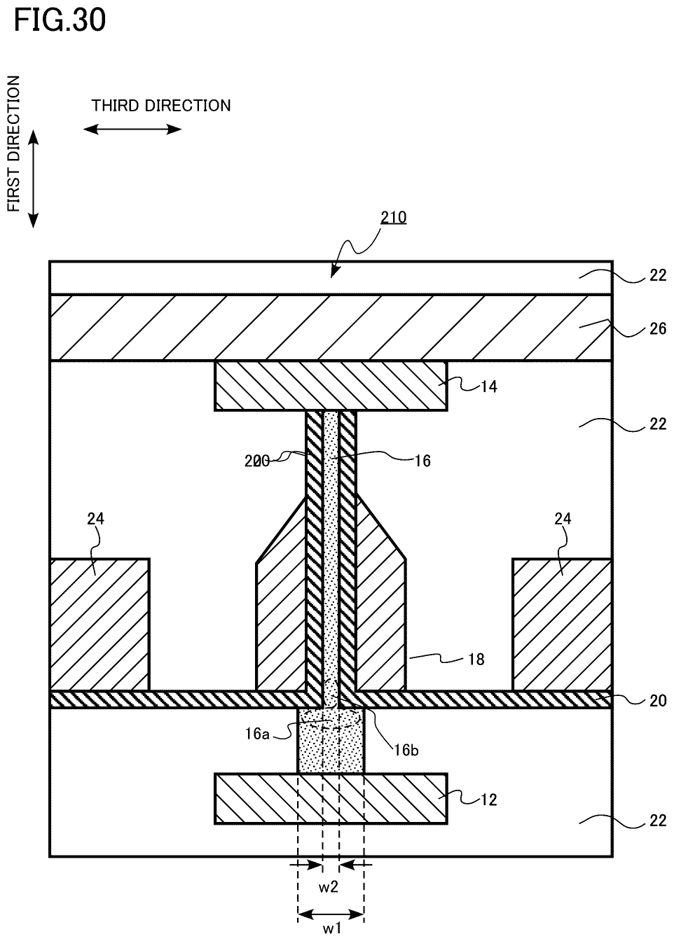

FIG. 30 is a schematic cross-sectional view of a semiconductor device according to a first modification example of the second embodiment. FIG. 30 is a diagram corresponding to FIG. 28 of the second embodiment.

In a transistor 210 according to the first modification example of the second embodiment, the gate insulating layer 20 is provided between the first region 16a and the gate electrode 18 in the first direction.

The width w2 of the second region 16b in the third direction is smaller than that in the transistor 200 according to the second embodiment. Therefore, in the oxide semiconductor layer 16 of the transistor 210 according to the second modification example, the cross-sectional area perpendicular to the first direction of the oxide semiconductor layer 16 surrounded by the gate electrode 18 is further reduced compared with, for example, the transistor 200 according to the second embodiment.

According to the transistor 210 according to the first modification example of the second embodiment, the cross-sectional area perpendicular to the first direction of the oxide semiconductor layer 16 surrounded by the gate electrode 18 is further reduced, so that, for example, the threshold voltage of the transistor 210 can be further increased.

In addition, in the oxide semiconductor layer 16 of the transistor 210 according to the first modification example of the second embodiment, the end of the gate insulating layer 20 on the lower electrode 12 side is further embedded in the oxide semiconductor layer 16. Therefore, for example, an increase in on-current or a reduction in leakage current can be further realized.

### Second Modification Example

A semiconductor device according to a second modification example of the second embodiment is different from the semiconductor device according to the second embodiment in that no gate insulating layer is provided between the first electrode and the gate electrode in the first direction.

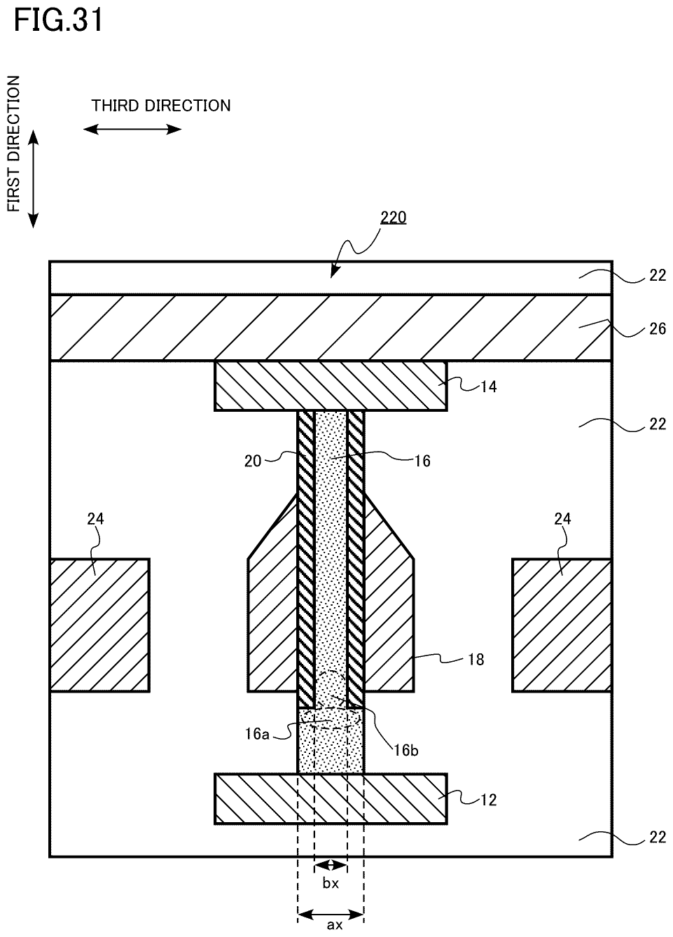

FIG. 31 is a schematic cross-sectional view of the semiconductor device according to the second modification example of the second embodiment. FIG. 31 is a diagram corresponding to FIG. 28 of the second embodiment.

In a transistor 220 according to the second modification example of the second embodiment, the gate insulating layer 20 is not provided between the lower electrode 12 and the gate electrode 18 in the first direction.

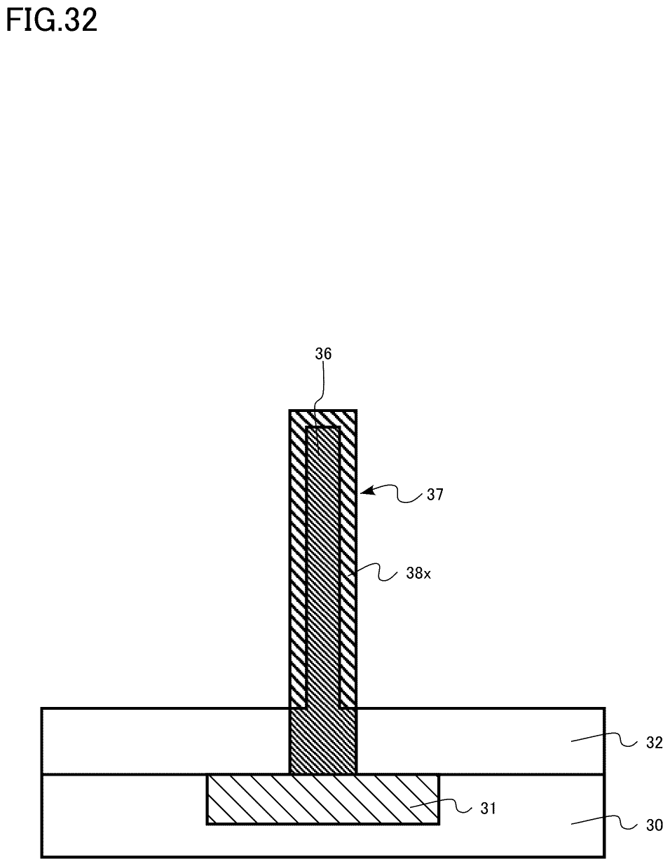

FIG. 32 is a schematic cross-sectional view showing an example of a method for manufacturing the semiconductor device according to the second modification example of the second embodiment.

For example, in the method for manufacturing the semiconductor device according to the first embodiment, an oxide film 38x is formed by oxidizing the amorphous silicon film 36 instead of forming the second silicon oxide film 38, which finally becomes the gate insulating layer 20, using a CVD method, after forming the pillar 37 of the amorphous silicon film 36. The oxide film 38x is formed by, for example, thermal oxidation or plasma oxidation of the amorphous silicon film 36. The oxide film 38x formed by oxidizing the amorphous silicon film 36 finally becomes the gate insulating layer 20.

As described above, according to the semiconductor devices according to the second embodiment and its modification examples, it is possible to realize a semiconductor device having excellent transistor characteristics.

### Third Embodiment

A semiconductor device according to a third embodiment is different from the semiconductor device according to the first embodiment in that the gate insulating layer includes a first film and a second film having a different chemical composition from the first film and the first film is interposed between the second film and the oxide semiconductor layer. Hereinafter, the description of a part of the content overlapping the first embodiment may be omitted.

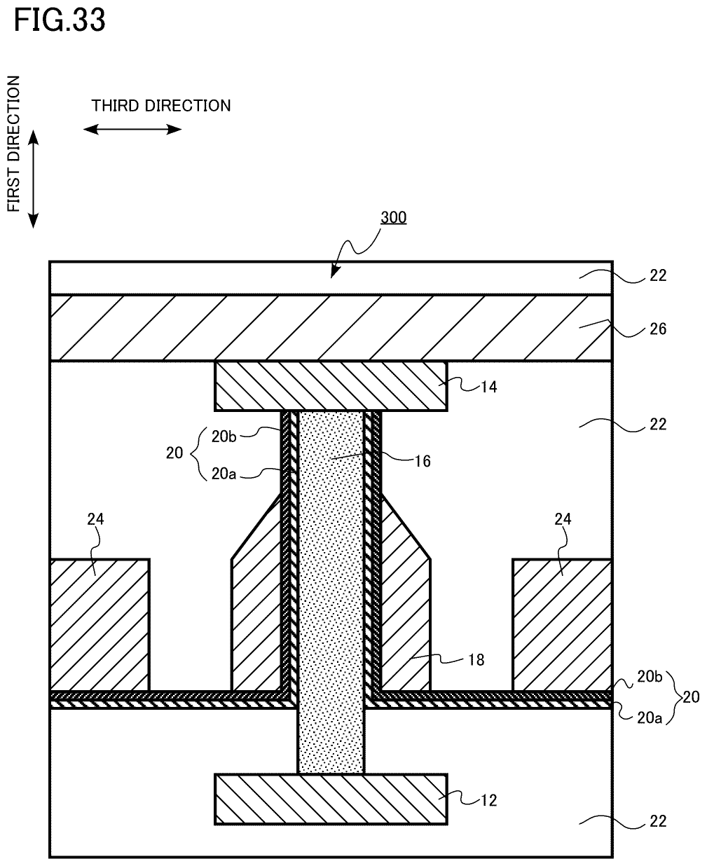

FIG. 33 is a schematic cross-sectional view of the semiconductor device according to the third embodiment. FIG. 33 is a diagram corresponding to FIG. 1 of the first embodiment.

A gate insulating layer 20 of a transistor 300 according to the third embodiment includes a first film 20a and a second film 20b. The first film 20a is interposed between the second film 20b and the oxide semiconductor layer 16. The first film 20a is provided between the oxide semiconductor layer 16 and the second film 20b. The gate insulating layer 20 has a stacked structure of the first film 20a and the second film 20b.

The chemical composition of the second film 20b is different from the chemical composition of the first film 20a. The first film 20a contains, for example, silicon oxide. The second film 20b contains, for example, a material having a higher dielectric constant than that of silicon oxide.

Examples of the material having a dielectric constant higher than that of silicon oxide contained in the second film 20b include silicon nitride, aluminum nitride, aluminum oxide, hafnium oxide, zirconium oxide, lanthanum oxide, yttrium oxide, and tantalum oxide.

According to the transistor 300 according to the third embodiment, the gate insulating layer 20 has a stacked structure of the first film 20a and the second film 20b, so that, for example, the threshold voltage of the transistor 300 can be increased. In addition, since the gate insulating layer 20 has a stacked structure of the first film 20a and the second film 20b, for example, the reliability of the gate insulating layer 20 can be improved.

As described above, according to the semiconductor device according to the third embodiment, it is possible to realize a semiconductor device having excellent transistor characteristics.

### Fourth Embodiment

A semiconductor device according to a fourth embodiment is different from the semiconductor device according to the first embodiment in that the gate electrode includes a first layer and a second layer having a different chemical composition from the first layer and the first layer is interposed between the second layer and the gate insulating layer. Hereinafter, the description of a part of the content overlapping the first embodiment may be omitted.

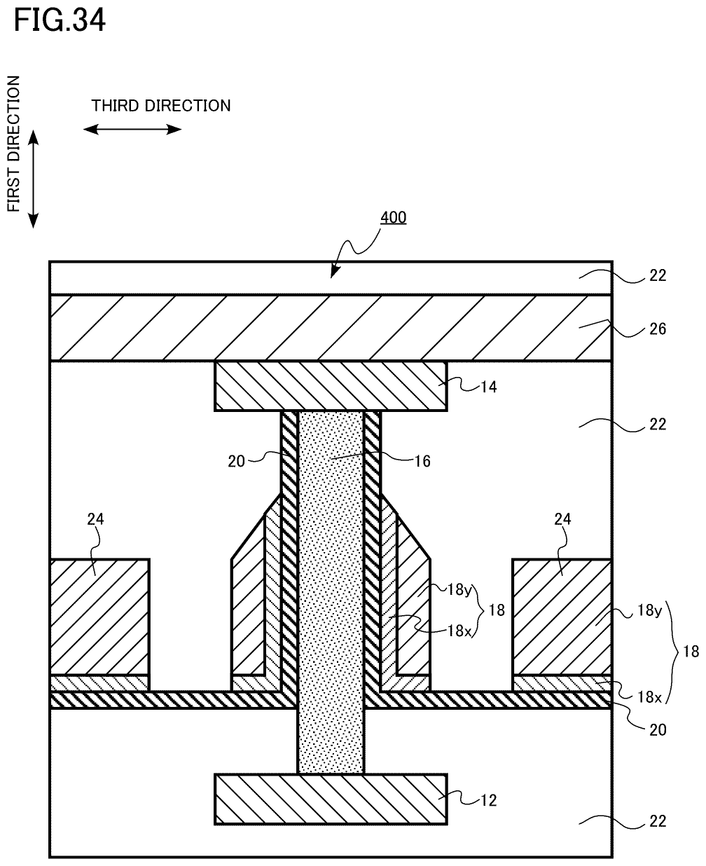

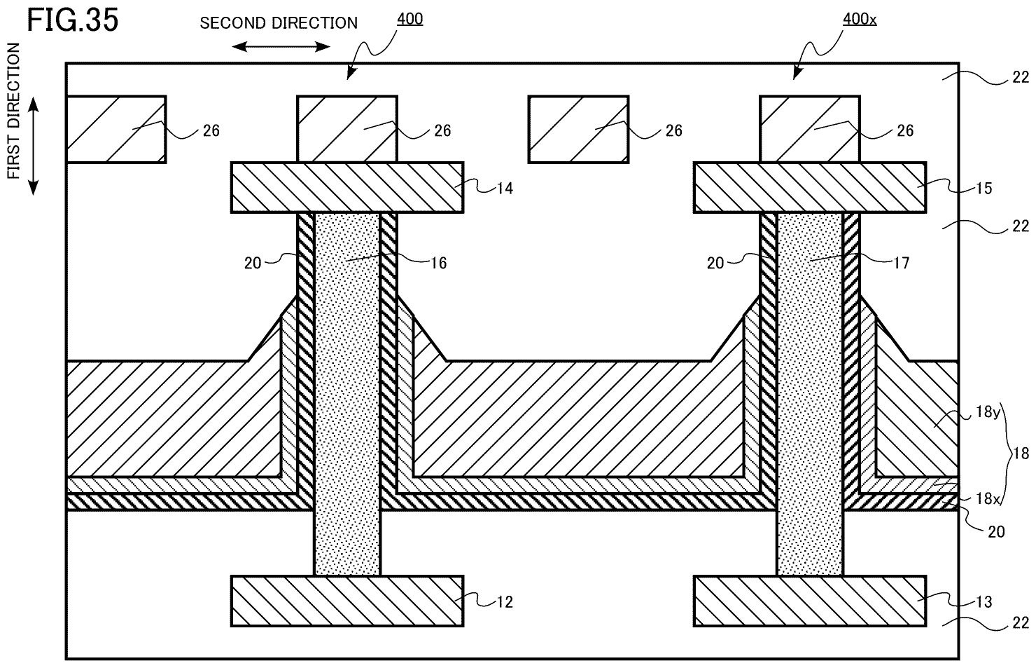

FIGS. 34 and 35 are schematic cross-sectional views of the semiconductor device according to the fourth embodiment. FIG. 34 is a diagram corresponding to FIG. 1 of the first embodiment. FIG. 35 is a diagram corresponding to FIG. 3 of the first embodiment.

A gate electrode 18 of a transistor 400 according to the fourth embodiment includes a first layer 18x and a second layer 18y. The first layer 18x is interposed between the second layer 18y and a gate insulating layer 20. The first layer 18x is provided between the gate insulating layer 20 and the second layer 18y. The gate electrode 18 has a stacked structure of the first layer 18x and the second layer 18y.

The chemical composition of the second layer 18y is different from the chemical composition of the first layer 18x. The second layer 18y contains a different material from the first layer 18x. The electrical resistivity of the material contained in the second layer 18y is, for example, lower than the electrical resistivity of the material contained in the first layer 18x.

The material contained in the first layer 18x is, for example, titanium nitride, tungsten nitride, or tantalum nitride. The material contained in the second layer 18y is, for example, tungsten or molybdenum.

According to the transistor 400 according to the fourth embodiment, the gate electrode 18 has a stacked structure of the first layer 18x and the second layer 18y, so that, for example, it is possible not only to control the threshold voltage of the transistor 400 but also to reduce the resistance of the gate electrode 18. Specifically, for example, a material having a work function suitable for optimizing the threshold voltage of the transistor 400 is applied to the first layer 18x. Then, for example, a material with low electrical resistivity is applied to the second layer 18y.

As described above, according to the semiconductor device according to the fourth embodiment, it is possible to realize a semiconductor device having excellent transistor characteristics.

### Fifth Embodiment

A semiconductor device according to a fifth embodiment is different from the semiconductor device according to the fourth embodiment in that the gate electrode further includes a third portion, the third portion faces the oxide semiconductor layer and is in contact with the gate insulating layer in a third direction perpendicular to the first direction and the second direction and has a third length in the first direction, and the third length is smaller than the first length. Hereinafter, the description of a part of the content overlapping the fourth embodiment may be omitted.

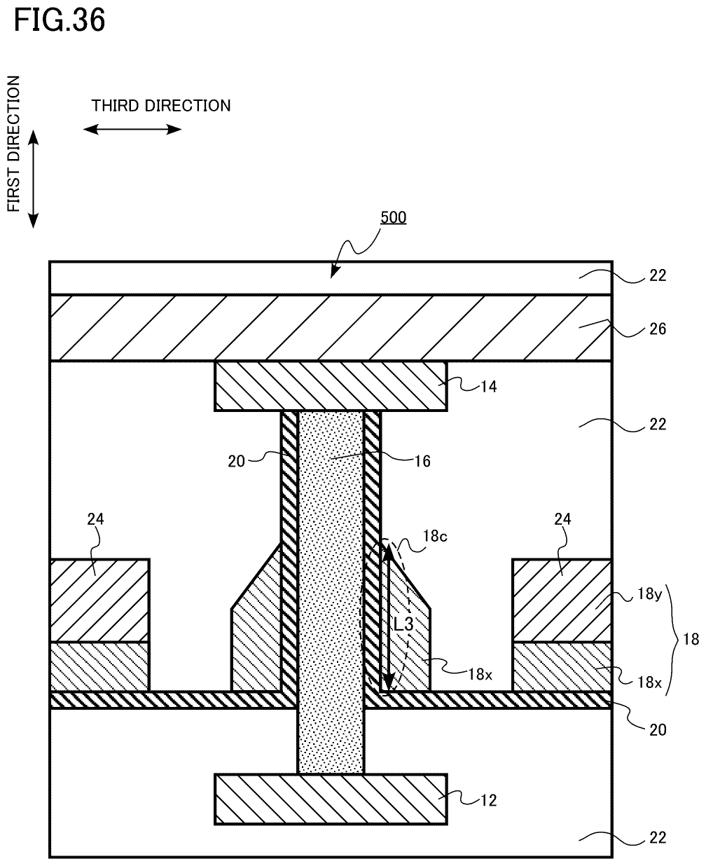

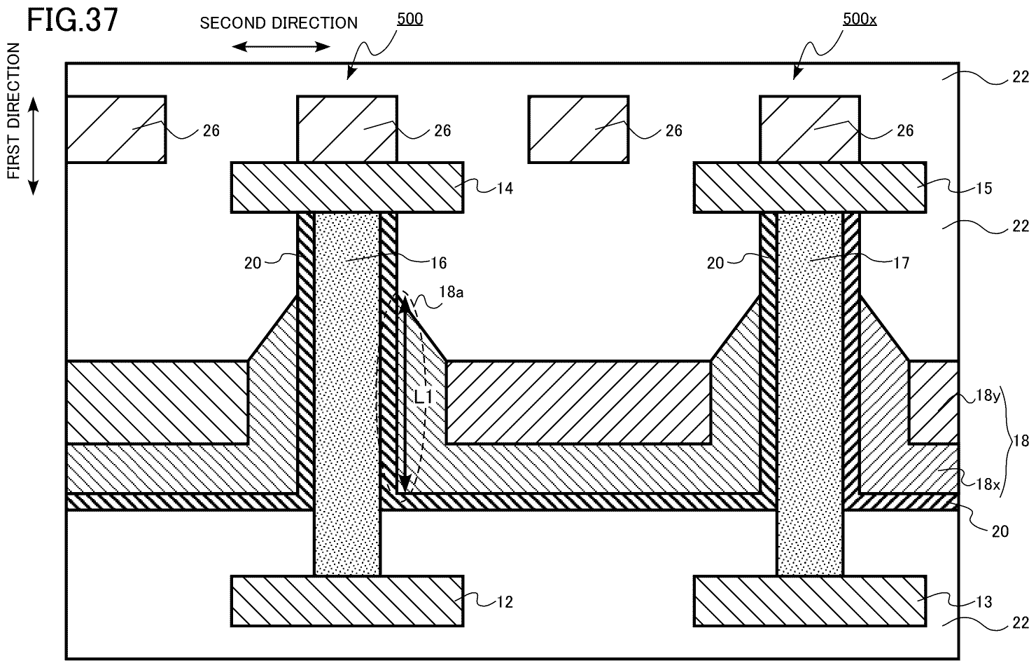

FIGS. 36 and 37 are schematic cross-sectional views of the semiconductor device according to the fifth embodiment. FIG. 36 is a diagram corresponding to FIG. 1 of the first embodiment. FIG. 37 is a diagram corresponding to FIG. 3 of the first embodiment.

A gate electrode 18 of a transistor 500 according to the fifth embodiment includes a first layer 18x and a second layer 18y, similarly to the transistor 400 according to the fourth embodiment. The first layer 18x is interposed between the second layer 18y and a gate insulating layer 20. The first layer 18x is provided between the gate insulating layer 20 and the second layer 18y. The gate electrode 18 has a stacked structure of the first layer 18x and the second layer 18y.

As shown in FIG. 36, the gate electrode 18 includes a third portion 18c. The third portion 18c is a portion that faces the oxide semiconductor layer 16 and is in contact with the gate insulating layer 20 in the third direction. The third portion 18c has a third length (L3 in FIG. 36) in the first direction.

In addition, as shown in FIG. 37, the gate electrode 18 includes a first portion 18a. The first portion 18a is a portion that faces the oxide semiconductor layer 16 and is in contact with the gate insulating layer 20 in the second direction. The first portion 18a has a first length (L1 in FIG. 37) in the first direction. The third length L3 is smaller than the first length L1.

The third length L3 is, for example, equal to or more than 0.5 times and equal to or less than 0.8 times the first length L1.

The gate electrode 18 provided in the third direction of the oxide semiconductor layer 16 does not include the second layer 18y. The gate electrode 18 provided in the third direction of the oxide semiconductor layer 16 is formed only of the first layer 18x.

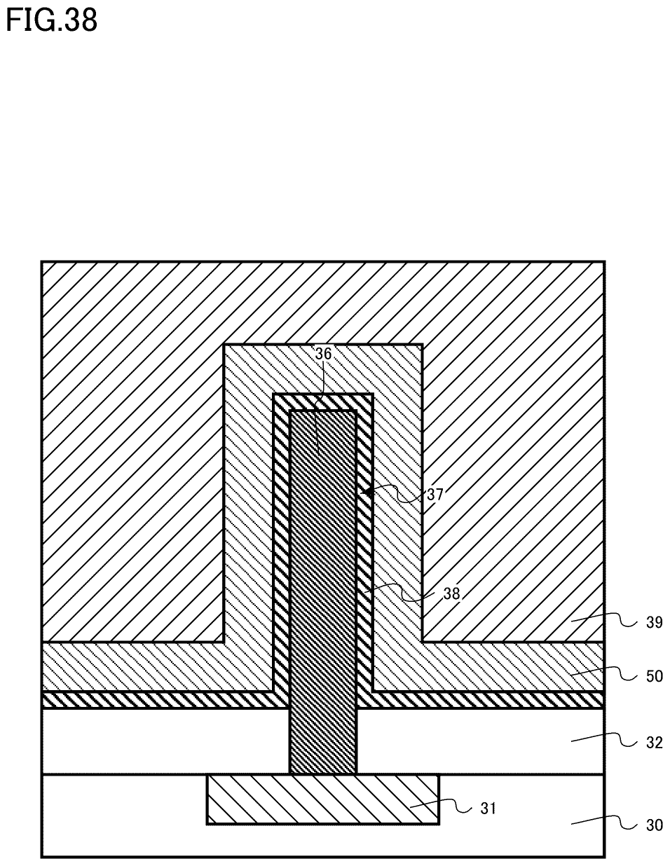

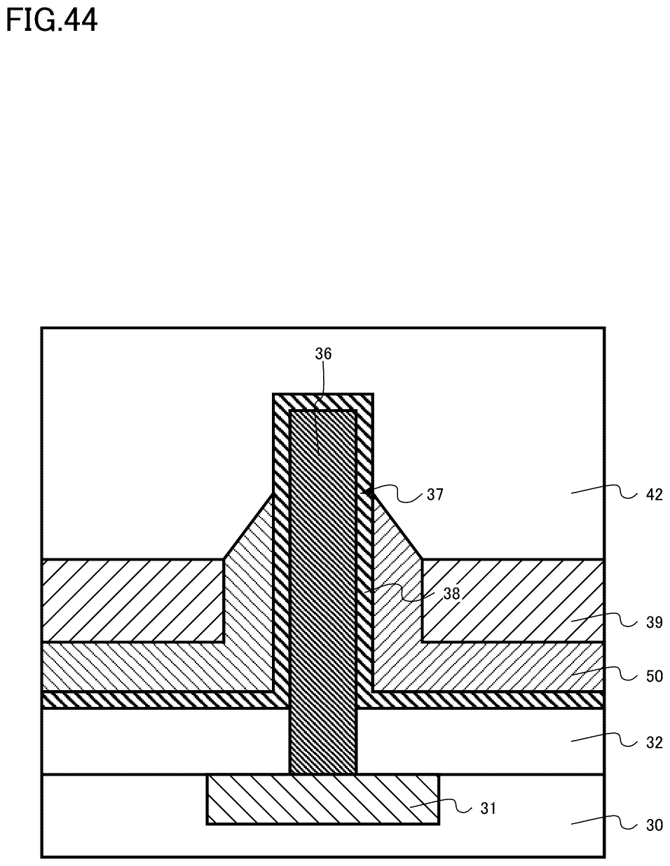

FIGS. 38 to 44 are schematic cross-sectional views showing an example of a method for manufacturing the semiconductor device according to the fifth embodiment. FIGS. 38 to 43 are diagrams corresponding to FIG. 36. FIG. 44 is a diagram corresponding to FIG. 37.

For example, in the method for manufacturing the semiconductor device according to the first embodiment, before the pillar 37 is covered with the tungsten film 39, a titanium nitride film 50 is formed. The tungsten film 39 is formed on the titanium nitride film 50 (FIG. 38).

The titanium nitride film 50 is formed by using, for example, a CVD method. The tungsten film 39 is formed by using, for example, a CVD method. A part of the titanium nitride film 50 and a part of the tungsten film 39 finally become the gate electrode 18 and the first wiring layer 24. A part of the titanium nitride film 50 becomes the first layer 18x. A part of the tungsten film 39 becomes the second layer 18y.

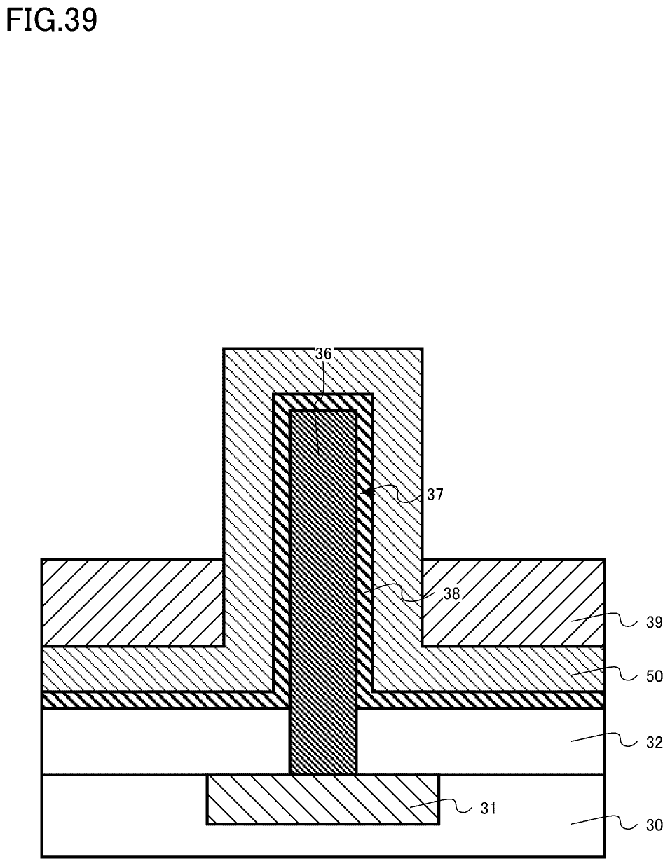

Then, a part of the tungsten film 39 is etched to expose the titanium nitride film 50 on the upper surface and the side surfaces of the pillar 37 (FIG. 39). The tungsten film 39 is etched by using, for example, an RIE method.

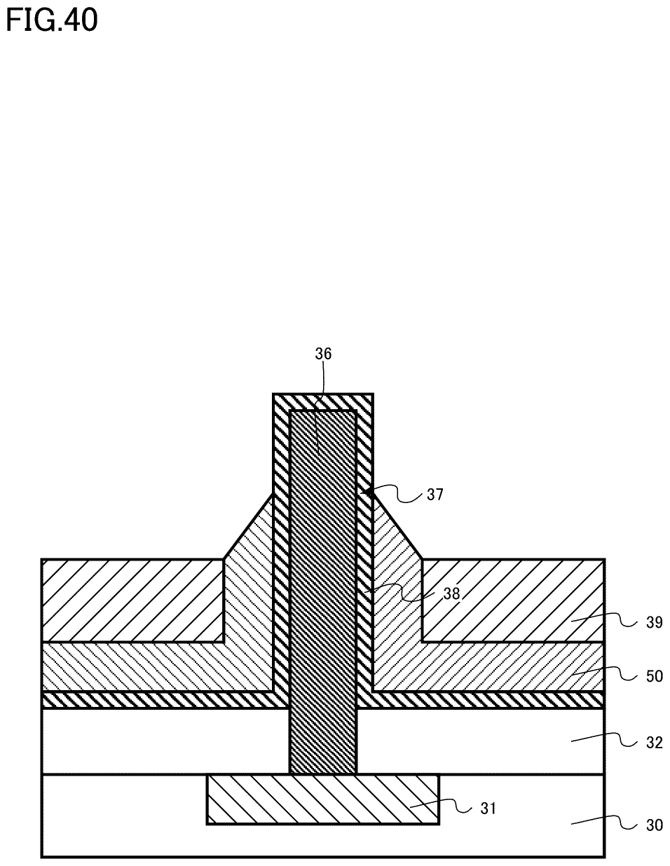

Then, the titanium nitride film 50 on the upper surface of the pillar 37 is etched to expose a part of the second silicon oxide film 38 on the side surfaces of the pillar 37 (FIG. 40). At this time, the titanium nitride film 50 is etched so that the titanium nitride film 50 along the side surfaces of the pillar 37 remains thicker than the other portions.

For example, by using a wet etching method, the titanium nitride film 50 along the pillar 37 can be left thick.

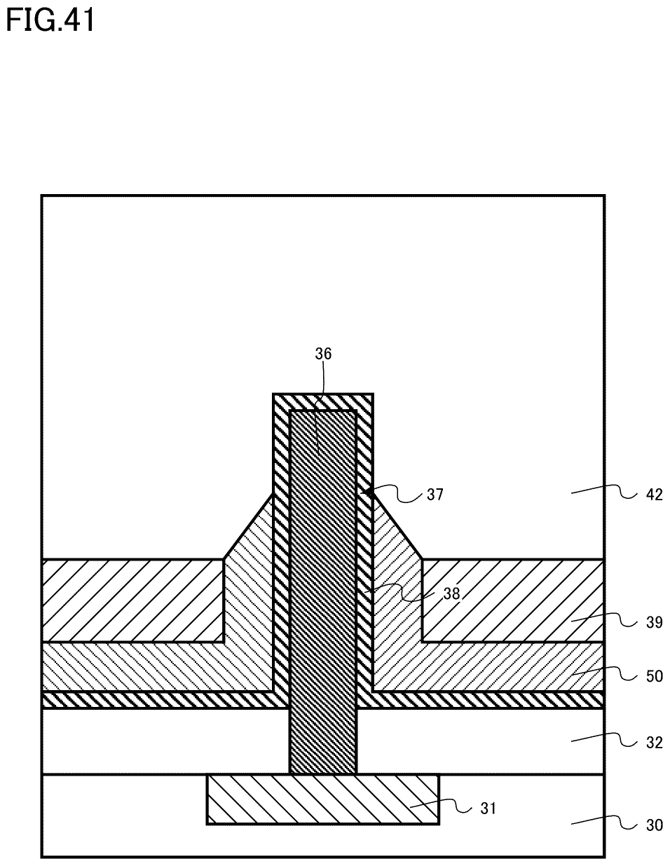

Then, the pillar 37 and the sidewalls 41 are covered with the third silicon oxide film 42 (FIG. 41). The third silicon oxide film 42 is formed by using, for example, a CVD method.

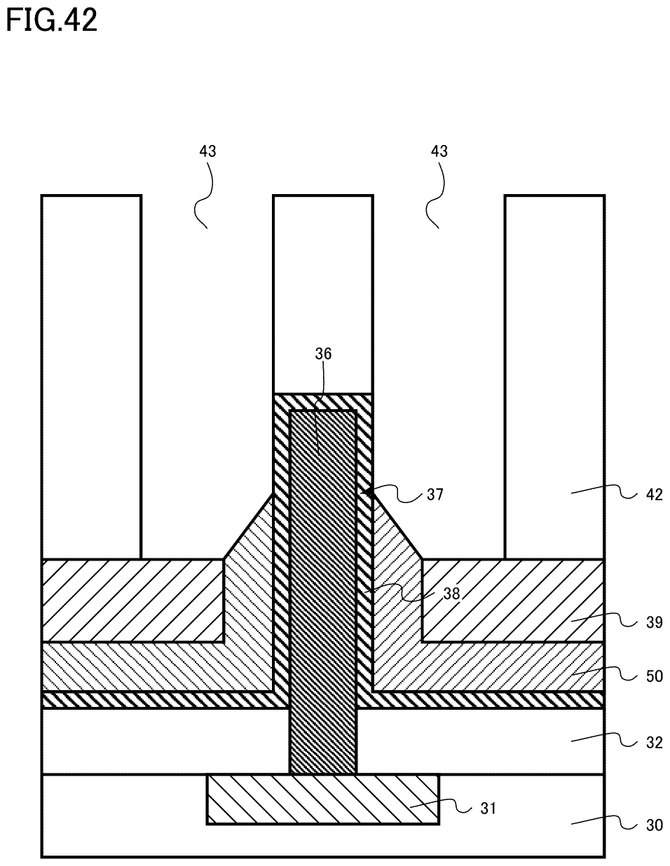

Then, the third silicon oxide film 42 is etched to form a second opening 43 where the titanium nitride film 50 and the tungsten film 39 are exposed (FIG. 42). The second opening 43 is formed by using a lithography method and an RIE method.

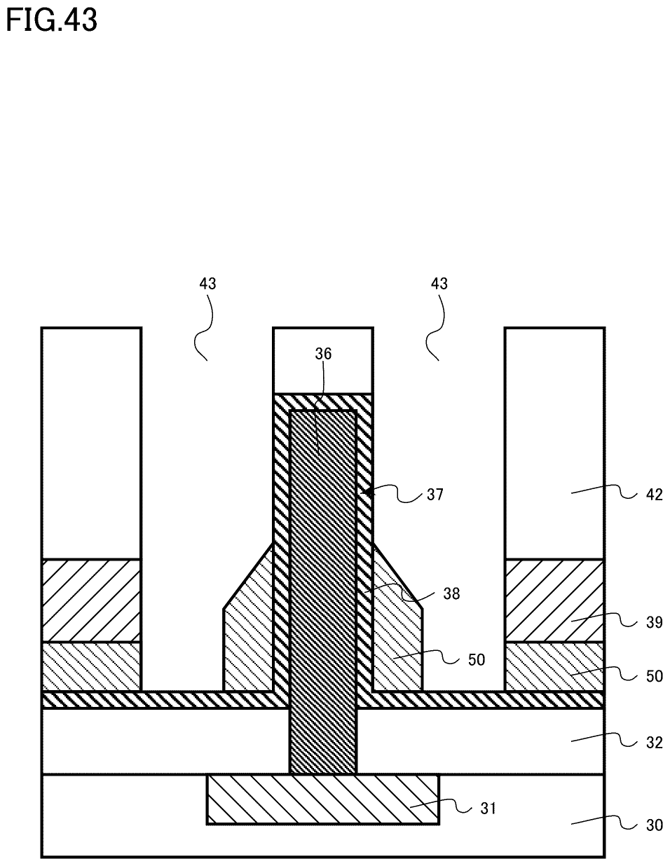

Then, the tungsten film 39 and the titanium nitride film 50 are etched using the third silicon oxide film 42 as a mask (FIG. 43). The tungsten film 39 and the titanium nitride film 50 are etched by using, for example, an RIE method.

Etching is performed in two steps, for example, etching of the tungsten film 39 and etching of the titanium nitride film 50. In the etching of the tungsten film 39, conditions that a selection ratio with respect to the titanium nitride film 50 is taken are selected. This ensures that the titanium nitride film 50 along the side surfaces of the pillar 37 remains.

In addition, FIG. 44 is a cross-sectional view taken in a direction perpendicular to FIG. 43. In this direction, the tungsten film 39 and the titanium nitride film 50 are all masked by the third silicon oxide film 42, and accordingly, the tungsten film 39 and the titanium nitride film 50 remain without being etched.

Thereafter, the transistor 500 according to the fifth embodiment can be manufactured by using a method similar to the manufacturing method according to the first embodiment.

According to the transistor 500 according to the fifth embodiment, as in the fourth embodiment, the gate electrode 18 has a stacked structure of the first layer 18x and the second layer 18y. Therefore, for example, it is possible not only to control the threshold voltage of the transistor 500 but also to reduce the resistance of the gate electrode 18. Specifically, a material having a work function suitable for optimizing the threshold voltage of the transistor 500 is applied to the first layer 18x. Then, a material with low electrical resistivity is applied to the second layer 18y.

When the gate electrode 18 provided in the third direction of the oxide semiconductor layer 16 is formed only of the first layer 18x as in the transistor 500, an increase in the electrical resistance of the gate electrode 18 around the oxide semiconductor layer 16 can be suppressed compared with a case where the gate electrode 18 has a stacked structure of the first layer 18x and the second layer 18y as in the transistor 400 according to the fourth embodiment. As described in the first embodiment, the effective width of the gate electrode 18 in the third direction decreases around the oxide semiconductor layer 16. At the interface between the first layer 18x and the second layer 18y, for example, an oxide film is formed. When the effective width is small and each of the first layer 18x and the second layer 18y is thin, the thin-line effect caused by electron scattering in the oxide film at the interface becomes apparent, and the electrical resistance of the gate electrode 18 increases in the third direction of the oxide semiconductor layer 16. In the transistor 500 according to the fifth embodiment, since the gate electrode 18 provided in the third direction of the oxide semiconductor layer 16 is formed only of the first layer 18x, there is no interface. Therefore, since the thin-line effect caused by electron scattering in the oxide film at the interface does not occur, an increase in the electrical resistance of the gate electrode 18 in the third direction of the oxide semiconductor layer 16 is suppressed. Therefore, for example, an increase in the wiring resistance of the gate electrode 18 in the second direction can be suppressed.

In addition, in the transistor 500 according to the fifth embodiment, the length of the gate electrode 18 in the third direction of the oxide semiconductor layer 16 along the oxide semiconductor layer 16 is reduced. This portion functions as an oxygen supply path after the transistor 500 is formed. Therefore, since it becomes easy to adjust the oxygen vacancy concentration in the oxide semiconductor layer 16, the characteristics of the transistor 500 are stable.

In addition, the transistor 500 according to the fifth embodiment can be manufactured without forming the sidewalls 41 used in the manufacturing method according to the first embodiment when forming the pattern of the gate electrode 18, for example. Therefore, the transistor 500 according to the fifth embodiment can be manufactured using the simpler manufacturing method.

As described above, according to the semiconductor device according to the fifth embodiment, it is possible to realize a semiconductor device having excellent transistor characteristics.

### Sixth Embodiment

A semiconductor memory device according to a sixth embodiment includes the semiconductor device according to the first embodiment and a capacitor electrically connected to the first electrode or the second electrode.

The semiconductor memory device according to the sixth embodiment is a semiconductor memory 600. The semiconductor memory device according to the sixth embodiment is a DRAM. In the semiconductor memory 600, the transistor 100 according to the first embodiment is used as a switching transistor of a memory cell in a DRAM.

Hereinafter, the description of a part of the content overlapping the first embodiment will be omitted.

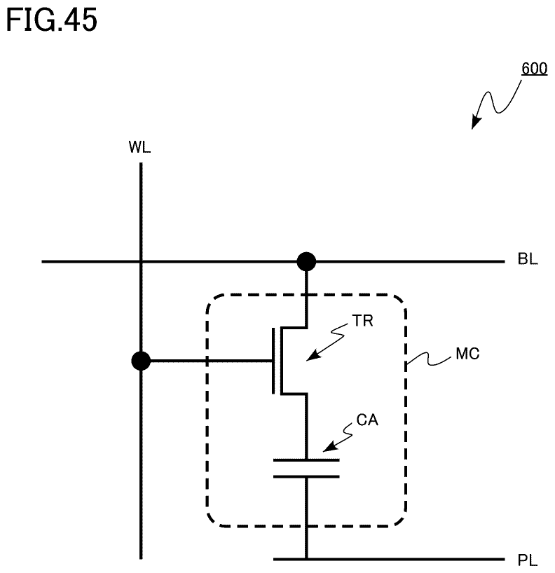

FIG. 45 is an equivalent circuit diagram of the semiconductor memory device according to the sixth embodiment. FIG. 45 illustrates a case where one memory cell MC is provided. However, for example, a plurality of memory cells MC may be provided in an array.

The semiconductor memory 600 includes the memory cell MC, a word line WL, a bit line BL, and a plate line PL. The memory cell MC includes a switching transistor TR and a capacitor CA. In FIG. 45, a region surrounded by the broken line is the memory cell MC.

The word line WL is electrically connected to the gate electrode of the switching transistor TR. The bit line BL is electrically connected to one of the source electrode and the drain electrode of the switching transistor TR. One electrode of the capacitor CA is electrically connected to the other one of the source electrode and the drain electrode of the switching transistor TR. The other electrode of the capacitor CA is connected to the plate line PL.

The memory cell MC stores data by storing charges in the capacitor CA. Data is written and read by turning on the switching transistor TR.

For example, data is written into the memory cell MC by turning on the switching transistor TR in a state in which a desired voltage is applied to the bit line BL.

In addition, for example, a voltage change in the bit line BL according to the amount of charge stored in the capacitor is detected by turning on the switching transistor TR, thereby reading the data of the memory cell MC.

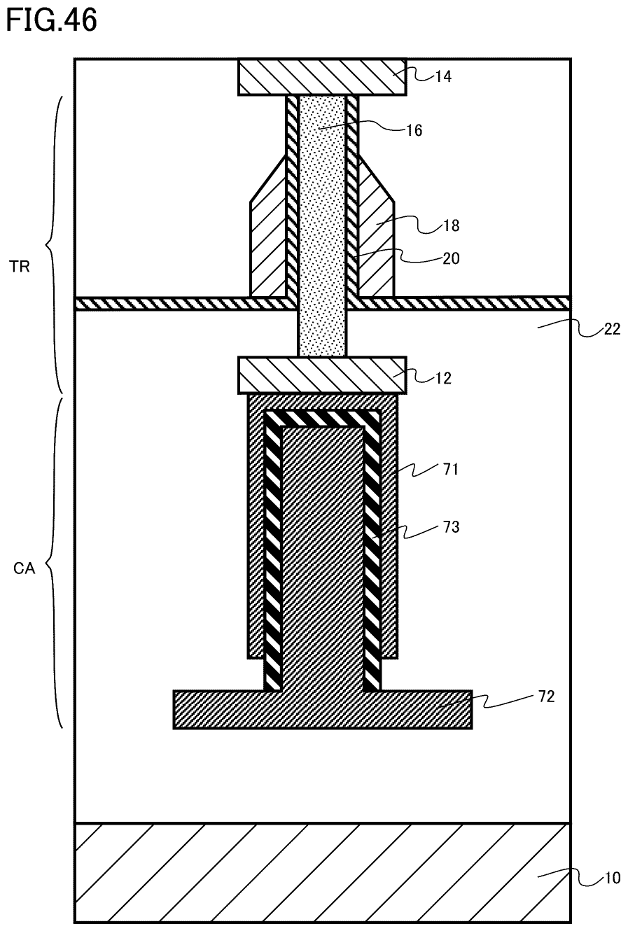

FIG. 46 is a schematic cross-sectional view of the semiconductor memory device according to the sixth embodiment. FIG. 46 shows a cross section of the memory cell MC of the semiconductor memory 600.

The semiconductor memory 600 includes a silicon substrate 10, the switching transistor TR, the capacitor CA, and an interlayer insulating layer 22.

The switching transistor TR includes a lower electrode 12, an upper electrode 14, an oxide semiconductor layer 16, a gate electrode 18, and a gate insulating layer 20.

The switching transistor TR has a structure similar to that of the transistor 100 according to the first embodiment.

The capacitor CA is provided between the silicon substrate 10 and the switching transistor TR. The capacitor CA is provided between the silicon substrate 10 and the lower electrode 12. The capacitor CA is electrically connected to the lower electrode 12.

The capacitor CA includes a cell electrode 71, a plate electrode 72, and a capacitor insulating film 73. The cell electrode 71 is electrically connected to the lower electrode 12. The cell electrode 71 is in contact with, for example, the lower electrode 12.

Each of the cell electrode 71 and the plate electrode 72 is, for example, a titanium nitride. The capacitor insulating film 73 has, for example, a stacked structure of zirconium oxide, aluminum oxide, and zirconium oxide.

The gate electrode 18 is electrically connected to, for example, the word line WL (not shown). The upper electrode 14 is electrically connected to, for example, the bit line BL (not shown). The plate electrode 72 is connected to, for example, the plate line PL (not shown).

In the semiconductor memory 600, an oxide semiconductor transistor having a very small channel leakage current during off operation is applied as the switching transistor TR. Therefore, a DRAM having an excellent charge storage characteristic is realized.

In addition, the switching transistor TR of the semiconductor memory 600 has a highly reliable gate insulating layer 20. Therefore, the reliability of the semiconductor memory 600 is improved.

In the sixth embodiment, a semiconductor memory to which the transistor according to the first embodiment is applied has been described as an example. However, the semiconductor memory of embodiments may be a semiconductor memory to which the transistors according to the second to fourth embodiments are applied.

In the sixth embodiment, a case where the capacitor CA is electrically connected to the lower electrode 12 has been described as an example, but the capacitor CA may be electrically connected to the upper electrode 14.

According to the semiconductor memory device according to the sixth embodiment, it is possible to realize a semiconductor memory device having excellent transistor characteristics.

### Seventh Embodiment

A semiconductor device according to a seventh embodiment is different from the semiconductor device according to the first embodiment in that the first wiring layer function as a gate electrode. Hereinafter, the description of a part of the content overlapping the first embodiment may be omitted.

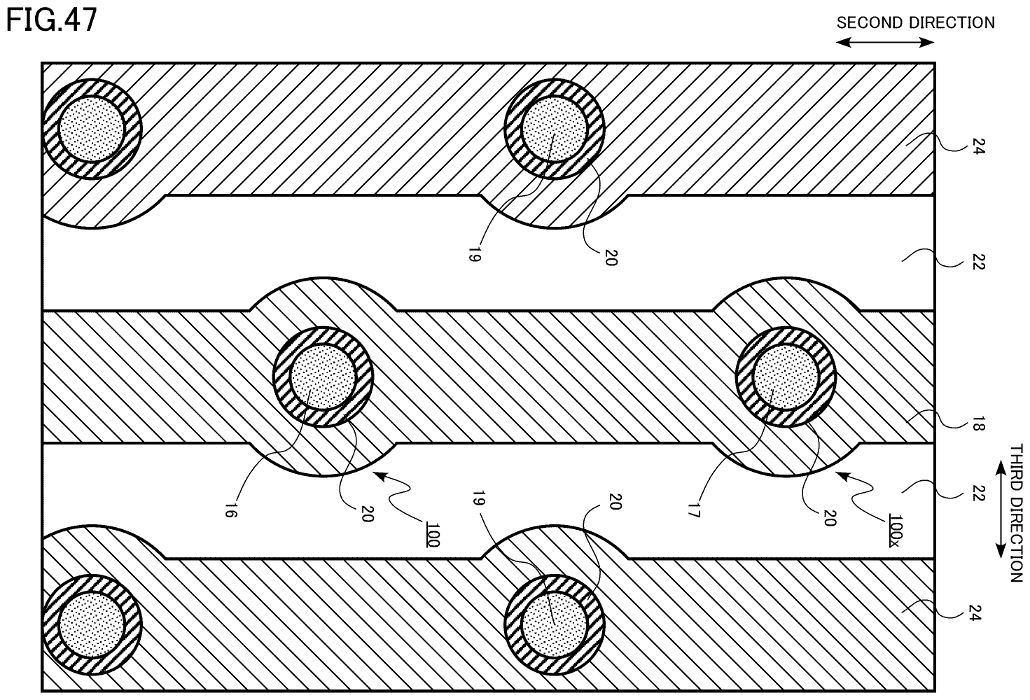

FIG. 47 is schematic cross-sectional views of the semiconductor device according to the seventh embodiment. FIG. 47 is a diagram corresponding to FIG. 2 of the first embodiment.

The semiconductor device according to a seventh embodiment includes transistors with the first wiring layer 24 as their gate electrode. The first wiring layer 24 has the same function as the gate electrode 18.

The first wiring layer 24 surrounds an oxide semiconductor layer 19 and the gate insulating layer 20. A channel of the transistor with the first wiring layer 24 as its gate electrode may form in the oxide semiconductor layer 19. As shown in FIG. 47, the transistors with the first wiring layer 24 as their gate electrode are arranged so that the positions in the second direction is between the positions in the second direction of the transistors with the gate electrode 18 as their gate electrode.

### Modification Example

A semiconductor device according to a modification example of the seventh embodiment is different from the semiconductor device according to the seventh embodiment in that arrangement of the transistors with the first wiring layer as their gate electrode is different.

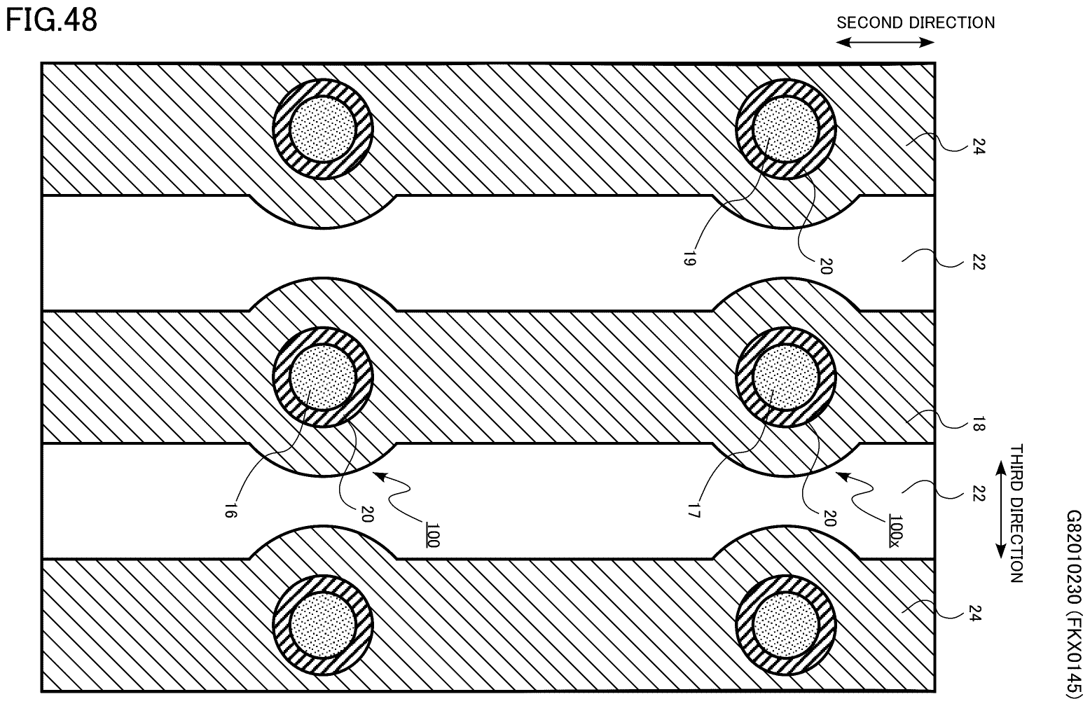

FIG. 48 is a schematic cross-sectional view of a semiconductor device according to a modification example of the seventh embodiment. FIG. 48 is a diagram corresponding to FIG. 47 of the seventh embodiment.

As shown in FIG. 48, the transistors with the first wiring layer 24 as their gate electrode are arranged so that positions in the second direction is as same as positions in the second direction of the transistors with the gate electrode 18 as their gate electrode.

As described above, according to the semiconductor devices according to the seventh embodiment and its modification example, it is possible to realize a semiconductor device having excellent transistor characteristics.

While certain embodiments have been described, these embodiments have been presented by way of example only, and are not intended to limit the scope of the inventions. Indeed, the semiconductor device and the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first electrode;
a second electrode;
a first oxide semiconductor layer provided between the first electrode and the second electrode;
a third electrode;
a fourth electrode;
a second oxide semiconductor layer provided between the third electrode and the fourth electrode, the second oxide semiconductor layer being separated from the first oxide semiconductor layer in a second direction perpendicular to a first direction connecting the first electrode and the second electrode;
a gate electrode surrounding the first oxide semiconductor layer and the second oxide semiconductor layer and extending in the second direction; and
a gate insulating layer provided between the gate electrode and the first oxide semiconductor layer,
wherein the gate electrode includes a first portion and a second portion,
the first portion faces the first oxide semiconductor layer and is in contact with the gate insulating layer in the second direction, and has a first length in the first direction,
the second portion is away from the first oxide semiconductor layer in the second direction by a distance corresponding to half a distance between the first oxide semiconductor layer and the second oxide semiconductor layer, and has a second length in the first direction, and
the first length is larger than the second length.

2. The semiconductor device according to claim 1,
wherein the gate insulating layer is provided between the gate electrode and the first electrode in the first direction.

3. The semiconductor device according to claim 1,
wherein the gate electrode further includes a third portion,
the third portion faces the first oxide semiconductor layer and is in contact with the gate insulating layer in a third direction perpendicular to the first direction and the second direction, and has a third length in the first direction, and
the third length is larger than the second length.

4. The semiconductor device according to claim 1,
wherein the first oxide semiconductor layer includes a first region and a second region provided between the first region and the second electrode,
the first region is in contact with the gate insulating layer in the first direction, and the second region is surrounded by the gate insulating layer, and
in a cross section parallel to the first direction, a first width of the first region in a third direction perpendicular to the second direction is larger than a second width of the second region in the third direction.

5. The semiconductor device according to claim 4,
wherein the gate insulating layer is provided between the first region and the gate electrode in the first direction.

6. The semiconductor device according to claim 4,
wherein a difference between the first width and the second width is equal to or more than 1 nm and equal to or less than 20 nm.

7. The semiconductor device according to claim 1,
wherein the gate insulating layer includes a first film and a second film having a different chemical composition from the first film, the first film being interposed between the second film and the first oxide semiconductor layer.

8. The semiconductor device according to claim 7,
wherein the first film contains silicon oxide, and the second film contains a material having a higher dielectric constant than a dielectric constant of silicon oxide.

9. The semiconductor device according to claim 1,
wherein the gate electrode includes a first layer and a second layer having a different chemical composition from the first layer, the first layer being interposed between the second layer and the gate insulating layer.

10. The semiconductor device according to claim 9,
wherein an electrical resistivity of a material contained in the second layer is lower than an electrical resistivity of a material contained in the first layer.

11. The semiconductor device according to claim 9,
wherein the gate electrode further includes a third portion,
the third portion faces the first oxide semiconductor layer and is in contact with the gate insulating layer in a third direction perpendicular to the first direction and the second direction, and has a third length in the first direction, and
the third length is smaller than the first length.

12. The semiconductor device according to claim 1, further comprising:
a first wiring layer provided in a third direction perpendicular to the first direction and the second direction of the gate electrode, extending in the second direction, and containing same material as the gate electrode,
wherein a fourth length of the first wiring layer in the first direction in a cross section parallel to the first direction and the third direction and including the first oxide semiconductor layer is smaller than the first length.

13. The semiconductor device according to claim 12,
wherein the gate insulating layer is in contact with the first wiring layer.

14. The semiconductor device according to claim 1,
wherein the first electrode is separated from the gate insulating layer in the first direction.

15. A semiconductor memory device, comprising:
the semiconductor device according to claim 1; and
a capacitor electrically connected to the first electrode or the second electrode.
